(19) United States
(12) Patent Application Publication
(10) Pub. No.: US 2025/0277305 A1
(43) Pub. Date: Sep. 4, 2025

(54) Selective Thin Film Deposition Method Using Area-Selective Atomic Layer Deposition Method, and Substrates Having Thin Films Selectively Formed Thereon

(71) Applicant: INCHEON NATIONAL UNIVERSITY RESEARCH & BUSINESS FOUNDATION, Incheon (KR)

(72) Inventors: Han-Bo-Ram LEE, Incheon (KR); Summal ZOHA, Incheon (KR)

(21) Appl. No.: 18/857,296

(22) PCT Filed: Mar. 16, 2023
(86) PCT No.: PCT/KR2023/003538

§ 371 Date: May 29, 2025

(30) Foreign Application Priority Data
Apr. 19, 2022 (KR) 10-2022-0047877
Mar. 16, 2023 (KR) 10-2023-0034369

(51) Int. Cl. C23C 16/04; C23C 16/02; C23C 16/455

(52) U.S. Cl. CPC C23C 16/04; C23C 16/02; C23C 16/45525

(57) ABSTRACT

The present invention relates to a selective thin-film deposition using an area-selective atomic layer deposition, and substrates having thin films selectively formed thereon, and more specifically to a selective thin film deposition method using an area-selective atomic layer deposition, and substrates having thin films selectively formed thereon, the method using an organothiol small molecule inhibitor so as to form thin films having different thicknesses on the surfaces of a substrate comprising a metal such as copper (Cu), a substrate comprising silicon dioxide (SiO2), and a substrate comprising a nitride such as titanium nitride (TiN).

### TECHNICAL FIELD

The present invention relates to a method for selectively depositing a thin film using area-selective atomic layer deposition and a substrate having thin films selectively formed thereon. More specifically, the present invention relates to a method for selectively depositing a thin film using area-selective atomic layer deposition, in which the surfaces of 3 or more substrates, that is, a substrate including a metal, a substrate including silicon dioxide (SiO₂) and a substrate including a nitride, are passivated using an organothiol small-molecule inhibitor to form thin films having different thicknesses, and a substrate having thin films selectively formed thereon.

### BACKGROUND ART

As the semiconductor industry advances in technology, the size of semiconductor devices continues to become smaller to meet the requirements of the semiconductor market, and it currently requires a size of 10 nm or less.

For this reason, the existing top-down semiconductor device manufacturing method, which includes repetitive lithography and etching processes, has physical limitations in manufacturing semiconductor devices of 10 nm or less. As one example, the performance and reliability of devices were deteriorated due to a lack of accurate device patterning or the misalignment of patterned features during device layering.

Atomic layer deposition (ALD) is a thin-film deposition technique that has significant advantages over other thin-film depositions in terms of uniformity, thickness control and conformality.

The self-limiting surface properties of the atomic layer deposition process can provide additional benefits beyond thin-film deposition and area-selective deposition (ASD). Specifically, by controlling surface chemical reactivity in a vacuum environment using appropriate chemical treatments, localized deposition can be performed in area-selective deposition. Through such area-selective deposition, an appropriate pattern can be utilized on the original surface and transferred from the bottom up without repeated lithography and etching processes. In addition, it can be utilized to create additional patterns within a 3D pattern, which is impossible with existing technology. Furthermore, it has the advantage of minimizing unwanted side effects that may occur in current complex processes and reducing manufacturing costs.

Area-selective atomic layer deposition (AS-ALD) is a deposition with excellent reliability among atomic layer deposition (ALD) methods. In addition, using an inhibitor in area-selective atomic layer deposition is an effective method for surface functionalization. The inhibitor selectively adsorbs to a surface and performs the function of passivation and selective area deactivation when performing atomic layer deposition (ALD). In the related art, self-assembled monolayers (SAM), small molecule inhibitors (SMI), precursor inhibitors (Pis) and the like are used as such inhibitors.

SAM is a self-assembling molecule that can inhibit growth, by adsorbing with surface sensitivity and surface selectivity. However, as the size of semiconductor devices is decreasing, thermal stability is low, and there are physical limitations in carrying out the semiconductor device manufacturing process using SAMs having a certain size.

SMI is generally a nanometer-sized molecule with a characteristic chemical adsorption reaction region, and has similar adsorption selectivity to SAM. This adsorption selectivity is determined by an inert ligand. By utilizing nanometer-sized SMI for area-selective deposition (ASD), the difficulties for high-volume manufacturing faced by SAM can be overcome. In addition, SMI does not require the adsorption process as a wet chemical method that SAM essentially performs. In conclusion, SMI is being proposed as a better method than SAM, which has been widely used in the past as an inhibitor.

### DISCLOSURE

### Technical Problem

An object of the present invention is to provide a method for selectively depositing a thin film using area-selective atomic layer deposition that has excellent vapor pressure, easy chamber transfer and can form a dense monolayer in a short period of time, by using an organothiol small-molecule inhibitor that is adsorbed on a substrate surface with surface sensitivity and surface selectivity such as SAM, and a substrate having thin films selectively formed thereon.

In addition, another object of the present invention is to provide a method for selectively depositing a thin film using area-selective atomic layer deposition, which forms thin films having different thicknesses on the surfaces of a substrate including a metal, a substrate including silicon dioxide (SiO₂) and a substrate including a nitride, by using an organothiol small molecule inhibitor that is adsorbed at different concentrations on the surfaces of the substrate including a metal, the substrate including silicon dioxide (SiO₂) and the substrate including a nitride, respectively, and a substrate having thin films selectively formed thereon.

### Technical Solution

In order to solve the above-described problems, the present invention provides a method for selectively depositing a thin film using area-selective atomic layer deposition, including step 1 of preparing a substrate on which a first substrate including a metal, a second substrate including silicon dioxide (SiO₂) and a third substrate including a nitride are arranged in parallel and integrated; step 2 of exposing the substrate to an organothiol small-molecule inhibitor; and step 3 of forming a thin film on a surface of a substrate exposed to the organothiol small-molecule inhibitor, by using area-selective atomic layer deposition (AS-ALD). The metal of the first substrate according to the present invention may be selected from the group consisting of copper (Cu), cobalt (Co), ruthenium (Ru), molybdenum (Mo) and tungsten (W), and preferably, it may be copper (Cu). In addition, the nitride of the third substrate according to the present invention may be selected from the group consisting of titanium nitride, molybdenum nitride, tungsten nitride and silicon nitride, and preferably, it may be titanium nitride. In addition, the thin film formed according to the present invention may be a thin film selected from the group consisting of a metal, a metal oxide and a silicon dielectric material, and preferably, it may be a hafnium oxide (HfO₂) thin film.

In a preferred embodiment of the present invention, the thickness of a thin film formed on a surface of the first substrate, the thickness of a thin film formed on a surface of the second substrate, and the thickness of a thin film formed on a surface of the third substrate may be different.

In a preferred embodiment of the present invention, the method for selectively depositing a thin film using area-selective atomic layer deposition according to the present invention may satisfy Condition (1) below:

A<B<C (1)
wherein in Condition (1) above, A represents the thickness of a thin film formed on a surface of the first substrate, B represents the thickness of a thin film formed on a surface of the second substrate, and C represents the thickness of a thin film formed on a surface of the third substrate.

In a preferred embodiment of the present invention, the organothiol small-molecule inhibitor may include a compound represented by Chemical Formula 1 below.

R¹—S—R² [Chemical Formula 1]

In Chemical Formula 1 above, R¹ and R² are each independently a C1 to C12 linear alkyl group, a C3 to C12 branched alkyl group or a C6 to C12 aryl group. Preferably, R¹ and R² are a C1 to C12 linear alkyl group, and more preferably are a C1 to C3 linear alkyl group.

In a preferred embodiment of the present invention, step 2 of the method for selectively depositing a thin film using area-selective atomic layer deposition according to the present invention may include step 2-1 of drying the substrate, introducing the substrate into a chamber having an internal temperature of about 300 to about 500° C. and a vacuum base pressure condition, and maintaining for about 1 to about 20 minutes; step 2-2 of purging the chamber, introducing an organothiol small-molecule inhibitor into the chamber while maintaining an internal temperature of the chamber at about 200 to about 500° C., and exposing the substrate to the organothiol small-molecule inhibitor for about 1 to about 100 seconds; and step 2-3 of cooling the substrate exposed to the organothiol small-molecule inhibitor to a temperature of about 15 to about 35° C.

In a preferred embodiment of the present invention, in step 2 of the method for selectively depositing a thin film using area-selective atomic layer deposition according to the present invention, the surface of the first substrate exposed to the organothiol small-molecule inhibitor may have a water contact angle of about 90° to about 100°, and the surface of the second substrate exposed to the organothiol small-molecule inhibitor may have a water contact angle of about 70° to about 80°.

In a preferred embodiment of the present invention, in step 2 of the method for selectively depositing a thin film using area-selective atomic layer deposition according to the present invention, the organothiol small-molecule inhibitor introduced into the chamber may undergo thermal dissociation, and be separated into alkylsulfanyl and alkyl, respectively, and the alkylsulfanyl may be adsorbed on a surface of the first substrate, and the alkyl may be adsorbed on a surface of the second substrate. In this case, the alkylsulfanyl may be preferably ethylsulfanyl, and the alkyl may be preferably ethyl.

In a preferred embodiment of the present invention, step 3 of the method for selectively depositing a thin film using area-selective atomic layer deposition according to the present invention may include step 3-1 of introducing a substrate exposed to the organothiol small-molecule inhibitor into a chamber, and heating to about 200 to about 350° C.; and step 3-2 of performing area-selective atomic layer deposition as a cycle of introducing a precursor for thin-film deposition into the chamber, exposing for about 1 to about 10 seconds, purging for about 50 to about 70 seconds, introducing a counter reactant into the chamber, exposing for about 1 to about 5 seconds, and purging for about 50 to about 70 seconds.

In a preferred embodiment of the present invention, the precursor for thin-film deposition may be a volatile precursor including a Group 3 to Group 16 compound, such as a titanium compound, a hafnium compound, a zirconium compound, a tantalum compound, a vanadium compound, a niobium compound, a molybdenum compound or a silicon compound.

In a preferred embodiment of the present invention, the precursor for thin-film deposition may include at least one selected from a compound represented by Chemical Formula 2 below, a compound represented by Chemical Formula 3 below, a compound represented by Chemical Formula 4 below and a compound represented by Chemical Formula 5 below.

(L₁)ₙM(NR³R⁴)₄₋ₙ [Chemical Formula 2]

In Chemical Formula 2 above, L₁ is a ligand selected from the group consisting of cyclopentadienyl and C1 to C12 alkyl-substituted cyclopentadienyl, M is a metal selected from the group consisting of titanium, hafnium and zirconium, R³ and R⁴ are each independently a C1 to C12 linear alkyl group or a C3 to C12 branched alkyl group, and n is 0, 1 or 2.

R⁵ₘM(OR⁶)₃₋ₘ [Chemical Formula 3]

In Chemical Formula 3 above, M is a metal selected from the group consisting of aluminum, hafnium and zirconium, R⁵ and R⁶ are each independently a C1 to C12 linear alkyl group or a C3 to C12 branched alkyl group, and m is 1 to 3.

(L₂)ₚMR⁷(OR⁸)₃₋ₚ [Chemical Formula 4]

In Chemical Formula 4 above, L₂ is a ligand selected from the group consisting of cyclopentadienyl and C1 to C12 alkyl-substituted cyclopentadienyl, M is a metal selected from the group consisting of titanium, hafnium and zirconium, R⁷ and R⁸ are each independently a C1 to C12 linear alkyl group or a C3 to C12 branched alkyl group, and p is 1 or 2.

(R⁹N)_{q}M(NR¹⁰R¹¹)_{4-q} [Chemical Formula 5]

In Chemical Formula 5 above, M is a metal selected from the group consisting of vanadium, niobium, tantalum, molybdenum and tungsten, R⁹, R¹⁰ and R¹¹ are each independently a C1 to C12 linear alkyl group or a C3 to C12 branched alkyl group, and q is 1 or 2.

In a preferred embodiment of the present invention, the compound represented by Chemical Formula 2 may be tetrakis(dimethylamino)hafnium (TDMAH), tetrakis(diethylamino)hafnium (TDEAH), tetrakis(ethylmethylamino)hafnium (TEMAH), cyclopentadienyltris(dimethylamino)hafnium (CpHf(NMe₂)₃), methylcyclopentadienyltris(dimethylamino)hafnium ((MeCp)Hf(NMe₂)₃), ethylcyclopentadienyltris(dimethylamino)hafnium ((EtCp)Hf(NMe₂)₃), (n-propylcyclopentadienyl)tris(dimethylamino)hafnium ((n-PrCp)Hf(NMe₂)₃), cyclopentadienyltris(methylethylamino)hafnium (CpHf(NMeEt)₃), methylcyclopentadienyltris(methylethylamino)hafnium ((MeCp)Hf(NMeEt)₃), ethylcyclopentadienyltris(methylethylamino)hafnium ((EtCp)Hf(NMeEt)₃), cyclopentadienyltris(diethylamino)hafnium (CpHf(NEt₂)₃), methylcyclopentadienyltris(diethylamino)hafnium ((MeCp)Hf(NEt₂)₃), ethylcyclopentadienyltris(diethylamino)hafnium ((EtCp)Hf(NEt₂)₃), bis(cyclopentadienyl)bis(dimethylamino)hafnium (Cp₂Hf(NMe₂)₂), bis(methylcyclopentadienyl)bis(dimethylamino)hafnium ((MeCp)₂Hf(NMe₂)₂), bis(ethylcyclopentadienyl)bis(dimethylamino)hafnium ((EtCp)₂Hf(NMe₂)₂), bis(cyclopentadienyl)bis(methylethylamino)hafnium (Cp₂Hf(NMeEt)₂), bis(methylcyclopentadienyl)bis(methylethylamino)hafnium ((MeCp)₂Hf(NMeEt)₂), bis(ethylcyclopentadienyl)bis(methylethylamino)hafnium ((EtCp)₂Hf(NMeEt)₂), bis(cyclopentadienyl)bis(diethylamino)hafnium (Cp₂Hf(NEt₂)₂), bis(methylcyclopentadienyl)bis(diethylamino)hafnium ((MeCp)₂Hf(NEt₂)₃), bis(ethylcyclopentadienyl)bis(diethylamino)hafnium ((EtCp)₂Hf(NEt₂)₂) or (n-propylcyclopentadienyl)tris(dimethylamino)zirconium ((n-PrCp)Zr(NMe₂)₃), but is not limited thereto.

In a preferred embodiment of the present invention, the compound represented by Chemical Formula 3 may be trimethylaluminum, triethylaluminum, dimethylaluminum isopropoxide or diethylaluminum isopropoxide, but is not limited thereto.

In a preferred embodiment of the present invention, the compound represented by Chemical Formula 4 may be CpHfMe(OMe)₂, CpZrMe(OMe)₂, (MeCp)HfMe(OMe)₂, (MeCp)ZrMe(OMe)₂, (EtCp)HfMe(OMe)₂ or (EtCp)ZrMe(OMe), but is not limited thereto.

In a preferred embodiment of the present invention, the compound represented by Chemical Formula 5 may be tert-butyliminotri(diethylamino)tantalum (TBTDET), tert-butyliminotri(dimethylamino)tantalum (TBTDMT), tert-butyliminotri(ethylmethylamino)tantalum (TBTEMT), ethyliminotri(diethylamino)tantalum (EITDET), ethyliminotri(dimethylamino)tantalum (EITDMT), ethyliminotri(ethylmethylamino)tantalum (EITEMT), tert-amyliminotri(dimethylamino)tantalum (TAIMAT), tert-amyliminotri(diethylamino)tantalum, pentakis(dimethylamino)tantalum, tert-amyliminotri(ethylmethylamino)tantalum, bis(tert-butylimino)bis(dimethylamino)tungsten (BTBMW), bis(tert-butylimino)bis(diethylamino)tungsten or bis(tert-butylimino)bis(ethylmethylamino)tungsten, but is not limited thereto.

In a preferred embodiment of the present invention, the precursor for thin-film deposition may include a compound represented by Chemical Formula 2-1 below.

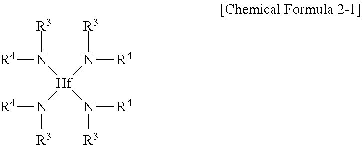

In Chemical Formula 2-1 above, R₃ and R₄ are each independently a C1 to C12 linear alkyl group or a C3 to C12 branched alkyl group.

In a preferred embodiment of the present invention, the counter reactant may include at least one selected from deionized water and hydrogen peroxide (H₂O₂).

In a preferred embodiment of the present invention, the area-selective atomic layer deposition is performed for about 2 cycles to about 100 cycles.

In a preferred embodiment of the present invention, in the area-selective atomic layer deposition, a thin film with a thickness of about 0.3 to about 0.8 Å may be formed on the surface of the first substrate per cycle. In this case, the thin film may be a hafnium oxide (HfO₂) thin film.

In a preferred embodiment of the present invention, in the area-selective atomic layer deposition, a thin film with a thickness of about 0.8 to about 1.5 Å may be formed on the surface of the second substrate per cycle. In this case, the thin film may be a hafnium oxide (HfO₂) thin film.

In a preferred embodiment of the present invention, in the area-selective atomic layer deposition, a thin film with a thickness of about 1.5 to about 2.5 Å may be formed on the surface of the third substrate per cycle. In this case, the thin film may be a hafnium oxide (HfO₂) thin film.

Meanwhile, the substrate having thin films selectively formed thereon according to the present invention may include a substrate on which a first substrate including a metal, a second substrate including silicon dioxide (SiO₂) and a third substrate including a nitride are arranged in parallel and integrated; and a thin film formed on a surface of the substrate. In this case, the metal of the first substrate may be selected from the group consisting of copper (Cu), cobalt (Co), ruthenium (Ru), molybdenum (Mo) and tungsten (W), and preferably, it may be copper (Cu). In addition, the nitride of the third substrate according to the present invention may be selected from the group consisting of titanium nitride, molybdenum nitride, tungsten nitride and silicon nitride, and preferably, it may be titanium nitride. In addition, the thin film formed on a surface of the substrate may be a thin film selected from the group consisting of a metal, a metal oxide and a silicon dielectric material, and preferably, it may be a hafnium oxide (HfO₂) thin film.

In a preferred embodiment of the present invention, alkylsulfanyl may be adsorbed on a surface of the first substrate.

In a preferred embodiment of the present invention, the alkylsulfanyl may be ethylsulfanyl.

In a preferred embodiment of the present invention, alkyl may be adsorbed on a surface of the second substrate.

In a preferred embodiment of the present invention, the alkyl may be ethyl.

In a preferred embodiment of the present invention, in the substrate having thin films selectively formed thereon according to the present invention, the thickness of a thin film formed on a surface of the first substrate, the thickness of a thin film formed on a surface of the second substrate, and the thickness of a thin film formed on a surface of the third substrate may be different.

In a preferred embodiment of the present invention, the substrate having thin films selectively formed thereon according to the present invention may satisfy Condition (1) below:

A<B<C (1)

In Condition (1) above, A represents the thickness of a thin film formed on a surface of the first substrate, B represents the thickness of a thin film formed on a surface of the second substrate, and C represents the thickness of a thin film formed on a surface of the third substrate.

### Advantageous Effects

The method for selectively depositing a thin film using the area-selective atomic layer deposition according to the present invention can form thin films having different thicknesses on the surfaces of 3 or more substrates, for example, a substrate including a metal, a substrate including silicon dioxide (SiO₂) and a substrate including a nitride.

### DESCRIPTION OF DRAWINGS

FIG. 1 is a schematic diagram showing that the dissociated organothiol small-molecule inhibitor is adsorbed on the surface of a substrate, when the substrate is exposed to an organothiol small-molecule inhibitor in step 2 of the method for selectively depositing a thin film using area-selective atomic layer deposition.

FIG. 2 is a schematic diagram showing that hafnium oxide (HfO₂) thin films are formed at different thicknesses on the surface of a substrate by the area-selective atomic layer deposition in step 3 of the method for selectively depositing a thin film using the area-selective atomic layer deposition.

FIG. 3 is a set of graphs showing the water contact angles measured according to the exposure time (DES) of the organothiol small-molecule inhibitor for each of a copper (Cu) substrate, a silicon dioxide (SiO₂) substrate and a titanium nitride (TiN) substrate exposed to the organothiol small-molecule inhibitor in Preparation Examples 1 to 3.

FIG. 4 a set of graphs showing the S-2p XPS spectra, by performing (X-ray photoelectron spectroscopy (XPS) analysis for each of a copper (Cu) substrate, a silicon dioxide (SiO₂) substrate and a titanium nitride (TiN) substrate exposed to the organothiol small-molecule inhibitor in Preparation Examples 1 to 3, while maintaining the internal temperature of the chamber at 400° C.

FIG. 5 is a set of graphs showing the S-2p XPS spectra, by performing XPS (X-ray photoelectron spectroscopy) analysis for the copper (Cu) substrate exposed to the organothiol small-molecule inhibitor in Preparation Example 1, while maintaining the internal temperature of the chamber at 200° C. and 300° C., respectively.

FIG. 6 is a graph of performing Fourier transform infrared spectroscopy (FT-IR) analysis for a silicon dioxide (SiO₂) substrate (=DES/SiO₂) exposed to the organothiol small-molecule inhibitor for 30 seconds while maintaining the internal temperature of the chamber at 400° C. in Preparation Example 2, and a silicon dioxide (SiO₂) substrate (=Bare SiO₂) not exposed to the organothiol small-molecule inhibitor, respectively.

FIG. 7 is a schematic diagram showing the adsorption mechanism of an organothiol small-molecule inhibitor (DES) on the surface of a silicon dioxide (SiO₂) substrate.

FIG. 8 is a graph showing the homogeneous selectivity measured according to the number of cycles of the area-selective atomic layer deposition between the copper (Cu) substrate in Comparative Example 1 and the copper (Cu) substrate in Example 1, between the silicon dioxide (SiO₂) substrate in Comparative Example 2, and the silicon dioxide (SiO₂) in Example 2, and between the titanium nitride (TiN) substrate in Comparative Example 3 and the titanium nitride (TiN) substrate in Example 3, respectively.

FIG. 9 is a graph showing the heterogeneous selectivity measured according to the number of cycles of the area-selective atomic layer deposition between the copper (Cu) substrate in Example 1 and the silicon dioxide (SiO₂) substrate in Example 2, between the silicon dioxide (SiO₂) substrate in Example 2 and the titanium nitride (TiN) substrate in Example 3, and between the titanium nitride (TiN) substrate in Example 3 and the copper (Cu) substrate in Example 1, respectively.

FIG. 10 is a graph showing the thickness of a hafnium oxide (HfO₂) thin film formed on the copper (Cu) substrate in Example 1, the thickness of a thin film formed on the silicon dioxide (SiO₂) substrate in Example 2, and the thickness of a hafnium oxide (HfO₂) thin film formed on the titanium nitride (TiN) substrate in Example 3, which are measured according to the number of cycles of the area-selective atomic layer deposition, respectively.

FIG. 11 is a graph showing analysis performed by using field-emission scanning electron microscopy (FE-SEM) for a titanium nitride (TiN) substrate having a silicon dioxide (SiO₂) pattern formed thereon in Preparation Example 1, a titanium nitride (TiN) substrate having a silicon dioxide (SiO₂) pattern formed thereon in Comparative Preparation Example 1, a titanium nitride (TiN) substrate having a copper (Cu) pattern formed thereon in Preparation Example 2 and a titanium nitride (TiN) substrate having a copper (Cu) pattern formed thereon in Comparative Preparation Example 2, respectively.

FIG. 12 is a set of graphs showing analysis performed through Auger electron spectroscopy (AES) for a titanium nitride (TiN) substrate having s silicon dioxide (SiO₂)-copper (Cu) pattern formed thereon in Preparation Example 3.

### MODES OF THE INVENTION

Hereinafter, with reference to the attached drawings, embodiments of the present invention will be described in detail so that those skilled in the art can easily practice the present invention. The present invention may be implemented in many different forms and is not limited to the embodiments described herein. The same reference numerals are assigned for identical or similar components throughout the specification.

As used herein, the term “substantially free” is defined as less than 0.001 weight percent (wt %), and includes 0.000 weight percent (wt %). In addition, the term “free” means 0.000 wt %.

As used herein, the term “about” is intended to correspond to +5% of the defined number.

The method for selectively depositing a thin film using area-selective atomic layer deposition according to the present invention includes step 1 to step 3.

First of all, in step 1 of the method for selectively depositing a thin film using area-selective atomic layer deposition according to the present invention, a first substrate, a second substrate and a third substrate are arranged in parallel to prepare an integrated substrate. In this case, the first substrate, the second substrate and the third substrate may each be a substrate including different materials, and the first substrate may include a metal selected from the group consisting of copper (Cu), cobalt (Co), ruthenium (Ru), molybdenum (Mo) and tungsten (W), and particularly preferably include copper (Cu), the second substrate may include silicon dioxide (SiO₂), and the third substrate may include a nitride selected from the group consisting of titanium nitride, molybdenum nitride, tungsten nitride and silicon nitride, and particularly preferably include titanium nitride (TiN).

Next, in step 2 of the method for selectively depositing a thin film using area-selective atomic layer deposition according to the present invention, the substrate prepared in step 1 may be exposed to an organothiol small-molecule inhibitor.

In this case, the organothiol small-molecule inhibitor may include a compound represented by Chemical Formula (1) below.

R¹—S—R² [Chemical Formula 1]

In Chemical Formula 1 above, R¹ and R² are each independently a C1 to C12 linear alkyl group, a C3 to C12 branched alkyl group or a C6 to C12 aryl group. Preferably, R¹ and R² are a C1 to C12 linear alkyl group, and more preferably are a C1 to C3 linear alkyl group.

In addition, the organothiol small-molecule inhibitor may have a weight average molecular weight of about 300 or less, preferably, about 30 to about 150, and more preferably, about 60 to about 95.

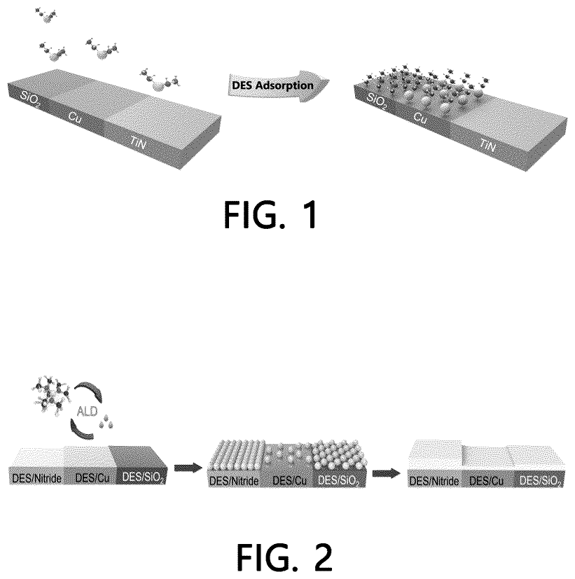

Specifically, when it is described with reference to FIG. 1, step 2 of the method for selectively depositing a thin film using area-selective atomic layer deposition according to the present invention may include steps 2-1 to 2-3.

First of all, in step 2-1 of the method for selectively depositing a thin film using area-selective atomic layer deposition according to the present invention, after drying the substrate prepared in step 1, it may be introduced into a chamber having an internal temperature of about 300° C. to about 500° C., and preferably, about 350° C. to about 450° C. and a vacuum base pressure condition, and maintained for about 1 minute to about 20 minutes, and preferably, about 5 minutes to about 15 minutes. If the internal temperature is less than about 300° C., there may be problems with adsorption of the organothiol small-molecule inhibitor, and if it exceeds about 500° C., there may be problems with desorption and decomposition of the organothiol small-molecule inhibitor.

Next, in step 2-2 of the method for selectively depositing a thin film using area-selective atomic layer deposition according to the present invention, the chamber is purged, and while the internal temperature of the chamber is maintained at about 200° C. to about 500° C., preferably, about 350° C. to about 450° C., and more preferably, about 390° C. to about 410° C., an organothiol small-molecule inhibitor is introduced into the chamber, and the substrate may be exposed to the organothiol small-molecule inhibitor for about 1 second to about 100 seconds, preferably, about 30 seconds to about 90 seconds, and more preferably, about 30 seconds to about 60 seconds. If the internal temperature of the chamber is less than about 200° C., there may be problems of inefficient adsorption of the organothiol small-molecule inhibitor, and if it exceeds about 500° C., there may be problems of desorption and decomposition of the organothiol small-molecule inhibitor.

Lastly, in step 2-3 of the method for selectively depositing a thin film using area-selective atomic layer deposition, the substrate that has been exposed to the organothiol small-molecule inhibitor in step 2-2 may be cooled to about 15° C. to about 35° C., and preferably, about 20° C. to about 30° C.

Meanwhile, in step 2 of the method for selectively depositing a thin film using area-selective atomic layer deposition according to the present invention, the surface of the first substrate exposed to the organothiol small-molecule inhibitor may have a water contact angle of about 90° to about 100°.

Additionally, in step 2 of the method for selectively depositing a thin film using area-selective atomic layer deposition according to the present invention, the surface of the second substrate exposed to the organothiol small-molecule inhibitor may have a water contact angle of about 70° to about 80°.

Additionally, in step 2-2 of the method for selectively depositing a thin film using area-selective atomic layer deposition according to the present invention, the organothiol small-molecule inhibitor introduced into the chamber undergoes thermal dissociation such that it is separated into alkylsulfanyl and alkyl, respectively, and the alkylsulfanyl may be adsorbed on the surface of the first substrate, and the alkyl may be adsorbed on the surface of the second substrate. Specifically, alkylsulfanyl may be ethylsulfanyl, and alkyl may be ethyl.

Finally, in step 3 of the method for selectively depositing a thin film using area-selective atomic layer deposition according to the present invention, area-selective atomic layer deposition (AS-ALD) may be used to form a thin film on the surface of the substrate exposed to the organothiol small-molecule inhibitor in step 2.

In this case, the thickness of a thin film formed on the surface of the first substrate, the thickness of a thin film formed on the surface of the second substrate, and the thickness of a thin film formed on the surface of the third substrate may be different, and preferably Condition (1) below may be satisfied.

A<B<C (1)

In Condition (1) above, A represents the thickness of a thin film formed on a surface of the first substrate, B represents the thickness of a thin film formed on a surface of the second substrate, and C represents the thickness of a thin film formed on a surface of the third substrate.

Specifically, when it is described with reference to FIG. 2, step 3 of the method for selectively depositing a thin film using area-selective atomic layer deposition according to the present invention may include steps 3-1 and 3-2.

First of all, in step 3-1 of the method for selectively depositing a thin film using area-selective atomic layer deposition according to the present invention, the substrate exposed to the organothiol small-molecule inhibitor in step 2 may be introduced into a chamber, and the substrate may be heated at about 200° C. to about 350° C., and preferably, about 250° C. to about 300° C. If the temperature of the substrate exposed to the organothiol small-molecule inhibitor is less than about 200° C., there may be problems of inefficient adsorption of the organothiol small-molecule inhibitor, and if it exceeds about 350° C., there may be problems of decomposition of the organothiol small-molecule inhibitor.

Next, in step 3-2 of the method for selective deposition of a thin film using the area-selective atomic layer deposition of the present invention, area-selective atomic layer deposition may be performed as a cycle of introducing a precursor for thin-film deposition into the chamber, exposing for about 1 second to about 10 seconds, preferably, about 2 seconds to about 6 seconds, purging for about 50 seconds to about 70 seconds, preferably, about 55 seconds to about 65 seconds, introducing a counter reactant into the chamber, exposing for about 1 second to about 5 seconds, preferably, about 1 second to 3 seconds, and purging for about 50 seconds to about 70 seconds, preferably, about 55 seconds to about 65 seconds.

As a precursor for thin-film deposition, it may include at least one selected from the group consisting of a compound represented by Chemical Formula 2 below, a compound represented by Chemical Formula 3 below, a compound represented by Chemical Formula 4 below and a compound represented by Chemical Formula 5 below.

(L₁)ₙM(NR³R⁴)₄₋ₙ [Chemical Formula 2]

In Chemical Formula 2 above, L₁ is a ligand selected from the group consisting of cyclopentadienyl and C1 to C12 alkyl-substituted cyclopentadienyl, M is a metal selected from the group consisting of titanium, hafnium and zirconium, R³ and R⁴ are each independently a C1 to C12 linear alkyl group or a C3 to C12 branched alkyl group, and n is 0, 1 or 2.

R⁵ₘM(OR⁶)₃₋ₘ [Chemical Formula 3]

In Chemical Formula 3 above, M is a metal selected from the group consisting of aluminum, hafnium and zirconium, R⁵ and R⁶ are each independently a C1 to C12 linear alkyl group or a C3 to C12 branched alkyl group, and m is 1 to 3.

(L₂)ₚMR⁷(OR⁸)₃₋ₚ [Chemical Formula 4]

In Chemical Formula 4 above, L₂ is a ligand selected from the group consisting of cyclopentadienyl and C1 to C12 alkyl-substituted cyclopentadienyl, M is a metal selected from the group consisting of titanium, hafnium and zirconium, R⁷ and R⁸ are each independently a C1 to C12 linear alkyl group or a C3 to C12 branched alkyl group, and p is 1 or 2.

(R⁹N)_{q}M(NR¹⁰R¹¹)_{4-q} [Chemical Formula 5]

In Chemical Formula 5 above, M is a metal selected from the group consisting of vanadium, niobium, tantalum, molybdenum and tungsten, R⁹, R¹⁰ and R¹¹ are each independently a C1 to C12 linear alkyl group or a C3 to C12 branched alkyl group, and q is 1 or 2.

The compound represented by Chemical Formula 2 may specifically be tetrakis(dimethylamino)hafnium (TDMAH), tetrakis(diethylamino)hafnium (TDEAH), tetrakis(ethylmethylamino)hafnium (TEMAH), cyclopentadienyltris(dimethylamino)hafnium (CpHf(NMe₂)₃), methylcyclopentadienyltris(dimethylamino)hafnium ((MeCp)Hf(NMe₂)₃), ethylcyclopentadienyltris(dimethylamino)hafnium ((EtCp)Hf(NMe₂)₃), (n-propylcyclopentadienyl)tris(dimethylamino)hafnium ((n-PrCp)Hf(NMe₂)₃), cyclopentadienyltris(methylethylamino)hafnium (CpHf(NMeEt)₃), methylcyclopentadienyltris(methylethylamino)hafnium ((MeCp)Hf(NMeEt)₃), ethylcyclopentadienyltris(methylethylamino)hafnium ((EtCp)Hf(NMeEt)₃), cyclopentadienyltris(diethylamino)hafnium (CpHf(NEt₂)₃), methylcyclopentadienyltris(diethylamino)hafnium ((MeCp)Hf(NEt₂)₃), ethylcyclopentadienyltris(diethylamino)hafnium ((EtCp)Hf(NEt₂)₃), bis(cyclopentadienyl)bis(dimethylamino)hafnium (Cp₂Hf(NMe₂)₂), bis(methylcyclopentadienyl)bis(dimethylamino)hafnium ((MeCp)₂Hf(NMe₂)₂), bis(ethylcyclopentadienyl)bis(dimethylamino)hafnium ((EtCp)₂Hf(NMe₂)₂), bis(cyclopentadienyl)bis(methylethylamino)hafnium (Cp₂Hf(NMeEt)₂), bis(methylcyclopentadienyl)bis(methylethylamino)hafnium ((MeCp)₂Hf(NMeEt)₂), bis(ethylcyclopentadienyl)bis(methylethylamino)hafnium ((EtCp)₂Hf(NMeEt)₂), bis(cyclopentadienyl)bis(diethylamino)hafnium (Cp₂Hf(NEt₂)₂), bis(methylcyclopentadienyl)bis(diethylamino)hafnium ((MeCp)₂Hf(NEt₂)₃), bis(ethylcyclopentadienyl)bis(diethylamino)hafnium ((EtCp)₂Hf(NEt₂)₂) or (n-propylcyclopentadienyl)tris(dimethylamino)zirconium ((n-PrCp)Zr(NMe₂)₃), but is not limited thereto.

In addition, the compound represented by Chemical Formula 3 may be trimethylaluminum, triethylaluminum, dimethylaluminum isopropoxide or diethylaluminum isopropoxide, but is not limited thereto.

In addition, the compound represented by Chemical Formula 4 may be CpHfMe(OMe)₂, CpZrMe(OMe)₂, (MeCp)HfMe(OMe)₂, (MeCp)ZrMe(OMe)₂, (EtCp)HfMe(OMe)₂ or (EtCp)ZrMe(OMe), but is not limited thereto.

In addition, the compound represented by Chemical Formula 5 may be tert-butyliminotri(diethylamino)tantalum (TBTDET), tert-butyliminotri(dimethylamino)tantalum (TBTDMT), tert-butyliminotri(ethylmethylamino)tantalum (TBTEMT), ethyliminotri(diethylamino)tantalum (EITDET), ethyliminotri(dimethylamino)tantalum (EITDMT), ethyliminotri(ethylmethylamino)tantalum (EITEMT), tert-amyliminotri(dimethylamino)tantalum (TAIMAT), tert-amyliminotri(diethylamino)tantalum, pentakis(dimethylamino)tantalum, tert-amyliminotri(ethylmethylamino)tantalum, bis(tert-butylimino)bis(dimethylamino)tungsten (BTBMW), bis(tert-butylimino)bis(diethylamino)tungsten or bis(tert-butylimino)bis(ethylmethylamino)tungsten, but is not limited thereto.

Most preferably, the precursor for thin-film deposition may include a compound represented by Chemical Formula 2-1 below.

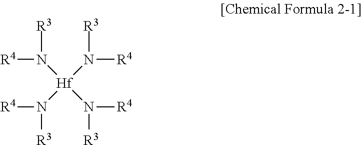

In Chemical Formula 2-1 above, R₃ and R₄ are each independently a C1 to C12 linear alkyl group or a C3 to C12 branched alkyl group, preferably, a C1 to C12 linear alkyl group, and more preferably, a C1 to C3 linear alkyl group.

In addition, the counter reactant may include at least one selected from deionized water and hydrogen peroxide (H₂O₂), and may preferably include deionized water.

Meanwhile, the area-selective atomic layer deposition may be performed for about 2 cycles to about 100 cycles, preferably, about 10 cycles to about 25 cycles, and more preferably, about 10 cycles to about 15 cycles.

Additionally, in the area-selective atomic layer deposition, a thin film with a thickness of about 0.3 Å to about 0.8 Å, preferably, about 0.4 Å to about 0.6 Å, may be formed on the surface of the first substrate per cycle.

Additionally, in the area-selective atomic layer deposition, a thin film with a thickness of about 0.8 Å to about 1.5 Å, preferably, about 1,1 Å to about 1.3 Å, may be formed on the surface of the second substrate per cycle.

Additionally, in the area-selective atomic layer deposition, a thin film with a thickness of about 1.5 Å to about 2.5 Å, preferably, 1.8 Å to about 2.2 Å, may be formed on the surface of the third substrate per cycle.

Meanwhile, the thin film formed on the surface of the substrate may be a thin film selected from the group consisting of a metal, a metal oxide and a silicon dielectric material, and preferably, it may be a hafnium oxide (HfO₂) thin film.

Furthermore, the substrate having thin films selectively formed thereon according to the present invention may include a substrate on which a first substrate including a metal, a second substrate including silicon dioxide (SiO₂) and a third substrate including a nitride are arranged in parallel and integrated; and a thin film formed on a surface of the substrate. In this case, alkylsulfanyl, preferably ethylsulfanyl, may be adsorbed on the surface of the first substrate. Additionally, alkyl, preferably ethyl, may be adsorbed on the surface of the second substrate.

Meanwhile, the metal of the first substrate may be selected from the group consisting of copper (Cu), cobalt (Co), ruthenium (Ru), molybdenum (Mo) and tungsten (W), and preferably, it may be copper (Cu).

Additionally, the nitride of the third substrate according to the present invention may be selected from the group consisting of titanium nitride, molybdenum nitride, tungsten nitride and silicon nitride, and preferably, it may be titanium nitride.

Additionally, the thin film formed on the surface of the substrate may be a thin film selected from the group consisting of a metal, a metal oxide and a silicon dielectric material, and preferably, it may be a hafnium oxide (HfO₂) thin film.

Furthermore, in the substrate having thin films selectively formed thereon according to the present invention, the thickness of a thin film formed on a surface of the first substrate, the thickness of a thin film formed on a surface of the second substrate, and the thickness of a thin film formed on a surface of the third substrate may be different, and preferably, Condition (1) below may be satisfied.

A<B<C (1)

In Condition (1) above, A represents the thickness of a thin film formed on a surface of the first substrate, B represents the thickness of a thin film formed on a surface of the second substrate, and C represents the thickness of a thin film formed on a surface of the third substrate.

Although the present invention has been described above with reference to embodiments, these are merely examples and do not limit the embodiments of the present invention, and those skilled in the art to which the embodiments of the present invention pertain will appreciate that various modifications and applications that re not exemplified above are possible without departing from the essential characteristics of the present invention. For example, each component specifically shown in the embodiments of the present invention can be modified and implemented. In addition, the differences related to such modifications and applications should be interpreted as being included in the scope of the present invention defined in the appended claims.

### Preparation Example 1: Exposure of Copper (Cu) Substrate to Organothiol Small-Molecule Inhibitor

(1) A copper (Cu) substrate was ultrasonically cleaned for 10 minutes sequentially with acetone, isopropyl alcohol and deionized water.
(2) After drying the cleaned copper (Cu) substrate with nitrogen gas (N₂ gas), it was introduced into a chamber having an internal temperature of 400° C. and a vacuum base pressure condition, and maintained for 10 minutes.
(3) A stainless-steel canister was prepared to maintain an internal temperature of 25° C. and store an organothiol small-molecule inhibitor. In this case, a compound represented by Chemical Formula 1 below was used as the organothiol small-molecule inhibitor.

R¹—S—R² [Chemical Formula 1]

In Chemical Formula 1 above, R¹ and R² are ethyl groups.
(4) The stainless-steel canister and the substrate were connected such that the copper (Cu) substrate could be exposed to the compound represented by Chemical Formula 1.
(5) The chamber was purged using nitrogen gas (N₂ gas), and while the internal temperature of the chamber was maintained at 200° C., 300° C. and 400° C., respectively, a copper (Cu) substrate was exposed to the compound represented by Chemical Formula 1 below for 0 seconds, 15 seconds, 30 seconds, 60 seconds and 90 seconds, respectively.
(6) The copper (Cu) substrate exposed to the compound represented by Chemical Formula 1 was cooled to a temperature of 25° C.

### Preparation Example 2: Exposure of Silicon Dioxide (SiO₂) Substrate to Organothiol Small-Molecule Inhibitor

(1) A silicon dioxide (SiO₂) substrate was ultrasonically cleaned for 10 minutes sequentially with acetone, isopropyl alcohol and deionized water.
(2) After drying the cleaned silicon dioxide (SiO₂) substrate with nitrogen gas (N₂ gas), it was introduced into a chamber having an internal temperature of 400° C. and a vacuum base pressure condition, and maintained for 10 minutes.
(3) A stainless-steel canister was prepared to maintain an internal temperature of 25° C. and store an organothiol small-molecule inhibitor. In this case, a compound represented by Chemical Formula 1 below was used as the organothiol small-molecule inhibitor.

R¹—S—R² [Chemical Formula 1]

In Chemical Formula 1 above, R¹ and R² are ethyl groups.
(4) The stainless-steel canister and the substrate were connected such that the silicon dioxide (SiO₂) substrate could be exposed to the compound represented by Chemical Formula 1.
(5) The chamber was purged using nitrogen gas (N₂ gas), and while the internal temperature of the chamber was maintained at 200° C., 300° C. and 400° C., respectively, the silicon dioxide (SiO₂) substrate was exposed to the compound represented by Chemical Formula 1 for 0 seconds, 15 seconds, 30 seconds, 60 seconds and 90 seconds, respectively.
(6) The silicon dioxide (SiO₂) substrate exposed to the compound represented by Chemical Formula 1 was cooled to a temperature of 25° C.

### Preparation Example 3: Exposure of Titanium Nitride (TiN) Substrate to Organothiol Small-Molecule Inhibitor

(1) A titanium nitride (TiN) substrate was ultrasonically cleaned for 10 minutes sequentially with acetone, isopropyl alcohol and deionized water.
(2) After drying the cleaned titanium nitride (TiN) substrate with nitrogen gas (N₂ gas), it was introduced into a chamber having an internal temperature of 400° C. and a vacuum base pressure condition, and maintained for 10 minutes.
(3) A stainless-steel canister was prepared to maintain an internal temperature of 25° C. and store an organothiol small-molecule inhibitor. In this case, a compound represented by Chemical Formula 1 below was used as the organothiol small-molecule inhibitor.

R¹—S—R² [Chemical Formula 1]

In Chemical Formula 1 above, R¹ and R² are ethyl groups.
(4) The stainless-steel canister and the substrate were connected such that the titanium nitride (TiN) substrate could be exposed to the compound represented by Chemical Formula 1 above.
(5) The chamber was purged using nitrogen gas (N₂ gas), and while the internal temperature of the chamber was maintained at 200° C., 300° C. and 400° C., respectively, the titanium nitride (TiN) substrate was exposed to the compound represented by Chemical Formula 1 above for 0 seconds, 15 seconds, 30 seconds, 60 seconds and 90 seconds, respectively.
(6) The titanium nitride (TiN) substrate exposed to the compound represented by Chemical Formula 1 was cooled to a temperature of 25° C.

### Experimental Example 1: Measurement of Water Contact Angle

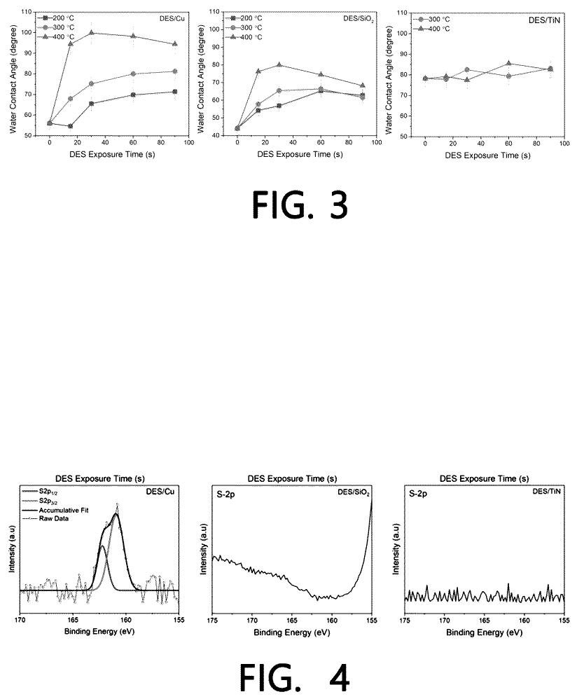

The water contact angle was measured for each of the copper (Cu) substrate, silicon dioxide (SiO₂) substrate and titanium nitride (TiN) substrate exposed to the organothiol small-molecule inhibitor in Preparation Example 1 to Preparation Example 3, and the results are shown in FIG. 3. Specifically, the left graph of FIG. 3 shows the water contact angle of the copper (Cu) substrate of Preparation Example 1 according to the exposure time (DES Exposure Time) of the organothiol small-molecule inhibitor, the middle graph of FIG. 3 shows the water contact angle of the silicon dioxide (SiO₂) substrate of Preparation Example 2 according to the exposure time (DES Exposure Time) of the organothiol small-molecule inhibitor, and the right graph of FIG. 3 shows the water contact angle of the titanium nitride (TiN) substrate of Preparation Example 3 according to the exposure time (DES Exposure Time) of the organothiol small-molecule inhibitor. In addition, the water contact angle was measured using a contact angle meter (SDL200TEZD, Femtobiomed), deionized water was used as the measurement source, and the droplet size was limited to 2 μL.

As can be confirmed in the left graph of FIG. 3, the water contact angle on the surface of the copper (Cu) substrate gradually increased from 55°. In addition, it was confirmed that the copper (Cu) substrate exposed to the organothiol small-molecule inhibitor while maintaining the internal temperature of the chamber at 200° C. was saturated at a water contact angle of about 750 as the exposure time of the organothiol small-molecule inhibitor was increased. In addition, the water contact angle of the copper (Cu) substrate exposed to the organothiol small-molecule inhibitor while maintaining the internal temperature of the chamber at 300° C. increased from 55° to about 68° 15 seconds after exposure to the organothiol small-molecule inhibitor and after 60 seconds, it was confirmed that it was saturated at a water contact angle of about 80°. In addition, the water contact angle of the copper (Cu) substrate exposed to the organothiol small-molecule inhibitor while maintaining the internal temperature of the chamber at 400° C. increased from 55° to about 95° 15 seconds after exposure to the organothiol small-molecule inhibitor, and after 30 seconds, it was confirmed that it was saturated at a contact angle of about 98°. Through these results, it was confirmed that the gradual increase in the water contact angle of the copper (Cu) substrate at internal temperatures of the chambers of 200° C. and 300° C. was due to limited adsorption of the organothiol small-molecule inhibitor at low temperatures.

As can be confirmed in the middle graph of FIG. 3, the water contact angle of the silicon dioxide (SiO₂) substrate exposed to the organothiol small-molecule inhibitor while maintaining the internal temperature of the chamber at 200° C. increased from 44° to about 55° 30 seconds after exposure to the organothiol small-molecule inhibitor, and after 60 seconds, it was confirmed that it was saturated at a water contact angle of about 62°. In addition, the water contact angle of the silicon dioxide (SiO₂) substrate exposed to the organothiol small-molecule inhibitor while maintaining the internal temperature of the chamber at 300° C. increased from 44° to about 65° 30 seconds after exposure to the organothiol small-molecule inhibitor, and it was confirmed that it was saturated. In addition, the water contact angle of the silicon dioxide (SiO₂) substrate exposed to the organothiol small-molecule inhibitor while maintaining the internal temperature of the chamber at 400° C. increased from 44° to about 76° 15 seconds after exposure to the organothiol small-molecule inhibitor, and after 30 seconds, it was confirmed that it was saturated at a water contact angle of about 80°.

As can be confirmed in the right graph of FIG. 3, it was confirmed that the titanium nitride (TiN) substrate exposed to the organothiol small-molecule inhibitor while maintaining the internal temperature of the chamber at 300° C. and 400° C., respectively, did not show a significant increase in water contact angle, even as the exposure time to the organothiol small-molecule inhibitor increased. Through these results, it was confirmed that the organothiol small-molecule inhibitor did not change the surface properties of the titanium nitride (TiN) substrate.

### Experimental Example 2: XPS Analysis

Each of the copper (Cu) substrate (exposure for 30 seconds), the silicon dioxide (SiO₂) substrate (exposure for 30 seconds) and the titanium nitride (TiN) substrate (exposure for 30 seconds) exposed to the organothiol small-molecule inhibitor while maintaining the internal temperature of the chamber at 400° C. in Preparation Example 1 to Preparation Example 3 was analyzed by X-ray photoelectron spectroscopy (XPS), and the results are shown in FIG. 4. Specifically, the S-2p peak was determined to confirm the presence of the organothiol small-molecule inhibitor on the copper (Cu) substrate, silicon dioxide (SiO₂) substrate and titanium nitride (TiN) substrate, and the left graph of FIG. 4 shows the S-2p XPS spectrum of the copper (Cu) substrate exposed to the organothiol small-molecule inhibitor while maintaining the internal temperature of the chamber at 400° C. in Preparation Example 1, the middle graph of FIG. 4 shows the S-2p XPS spectrum of the silicon dioxide (SiO₂) substrate exposed to the organothiol small-molecule inhibitor while maintaining the internal temperature of the chamber at 400° C. in Preparation Example 2, and the right graph of FIG. 4 shows the S-2p XPS spectrum of the titanium nitride (TiN) substrate exposed to the organothiol small molecule inhibitor while maintaining the internal temperature of the chamber at 400° C. in Preparation Example 3. In addition, the XPS analysis was performed using an XPS system (PHI-5000 Versa Probe II, ULVAC, Physical Electronics) that uses a monochromatic Al Kα line as a source.

As can be confirmed in the left graph of FIG. 4, it was confirmed that the S-2p peak was clearly shown in the S-2p XPS spectrum of the copper (Cu) substrate exposed to the organothiol small-molecule inhibitor while maintaining the internal temperature of the chamber at 400° C. in Preparation Example 1. The S-2p peak was in the range of 159 to 164 eV. Upon deconvolution of the S-2p peak, two chemical bonds of S-2p can be identified, including the binding energies of S2p_{3/2} at 161.0 eV and S2p_{1/2} at 162.5 eV, and these correspond to the spin orbital splitting of sulfur (S) and represent the interaction between sulfur (S) and carbon (C). The S-2p peak can be determined to be a thiol group of the organothiol small-molecule inhibitor being adsorbed on the surface of the copper (Cu) substrate. At high temperatures, the organothiol small-molecule inhibitor undergoes thermal dissociation and is separated into ethylsulfanyl. Due to the alkaline nature of the copper (Cu) substrate, only ethylsulfanyl, which has acidic properties, can be adsorbed. In conclusion, while maintaining the temperature inside the chamber at 400° C. in in Preparation Example 1, it was confirmed that ethylsulfanyl was adsorbed and bonded to the copper (Cu) substrate surface exposed to the organothiol small-molecule inhibitor. Meanwhile, it was found that ethylsulfanyl through adsorption passivates the surface of the copper (Cu) substrate by making it hydrophobic.

In addition, as can be confirmed in the left graph of FIG. 4, it was confirmed that the XPS spectrum of the copper (Cu) substrate exposed to the organothiol small-molecule inhibitor while maintaining the internal temperature of the chamber at 400° C. in Preparation Example 1 showed that there was no oxidized sulfur such as sulfonate showing a binding energy higher than 166 eV.

As can be confirmed in the middle graph of FIG. 4, in the S-2p XPS spectrum of the silicon dioxide (SiO₂) substrate exposed to the organothiol small-molecule inhibitor while maintaining the internal temperature of the chamber at 400° C. in Preparation Example 2, no S-2p characteristic peak was observed, indicating that no thiol group existed on the surface of the silicon dioxide (SiO₂) substrate.

In addition, as can be confirmed in the right graph of FIG. 4, in the S-2p XPS spectrum of the titanium nitride (TiN) substrate exposed to the organothiol small-molecule inhibitor while maintaining the internal temperature of the chamber at 400° C. in Preparation Example 3, no S-2p characteristic peak was observed, which also indicated that no thiol group existed on the surface of the titanium nitride (TiN) substrate.

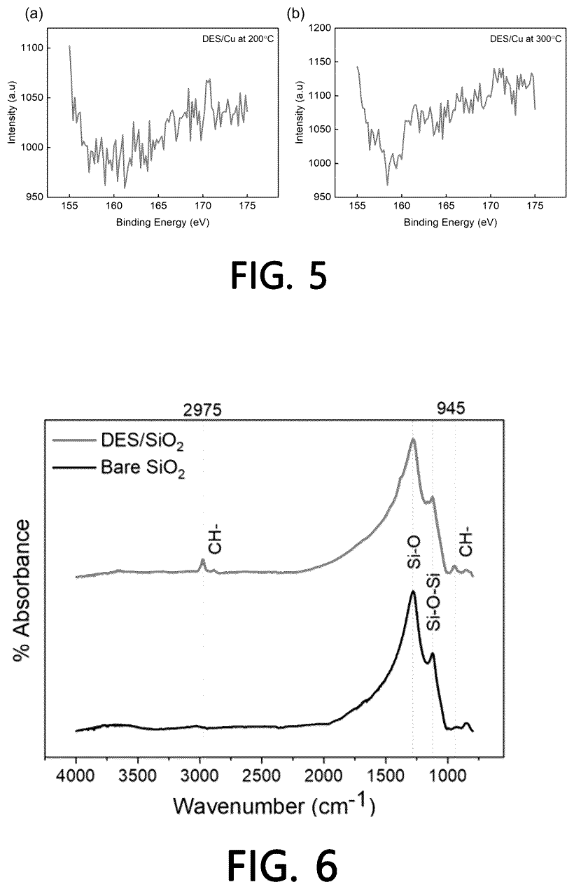

Additionally, the S-2p XPS spectra of the copper (Cu) substrate exposed to the organothiol small-molecule inhibitor for 30 seconds while maintaining the internal chamber temperature at 200° C. and 300° C., respectively, in Preparation Example 1 are shown in FIG. 5.

As can be confirmed in FIG. 5, it was confirmed that no S-2p peak was observed in the S-2p XPS spectrum of the copper (Cu) substrate exposed to the organothiol small-molecule inhibitor while maintaining the internal temperature of the chamber at 200° C. and 300° C., respectively in Preparation Example 1.

### Experimental Example 3: FT-IR Analysis

Each of the silicon dioxide (SiO₂) substrate (=DES/SiO₂) exposed to the organothiol small-molecule inhibitor for 30 seconds while maintaining the internal temperature of the chamber at 400° C. in Preparation Example 2 and the silicon dioxide (SiO₂) substrate not exposed to the organothiol small-molecule inhibitor was analyzed by Fourier transform infrared spectroscopy (FT-IR), and the results are shown in FIG. 6

In addition, FT-IR analysis was performed by measuring the FT-IR absorption spectrum at a wavenumber of 8,000 to 800 cm⁻¹ in attenuative total reflectance (ATR) mode using a Bruker spectrometer (VERTEX 80V, HYPERION 2000).

As can be confirmed in FIG. 6, it was confirmed that the spectrum of the silicon dioxide (SiO₂) substrate exposed to the organothiol small-molecule inhibitor while maintaining the internal temperature of the chamber at 400° C. in Preparation Example 2 showed a peak at 2,975 cm⁻¹, indicating the presence of CH stretch, and a peak at 945 cm⁻¹, indicating C—H bending vibration. These two peaks are peaks that were not observed on the silicon dioxide (SiO₂) substrate not exposed to the organothiol small-molecule inhibitor, which indicate that alkyl was present on the surface of the silicon dioxide (SiO₂) substrate exposed to the organothiol small-molecule inhibitor while maintaining the internal temperature of the chamber at 400° C. in Preparation Example 2. Through these results, it was confirmed that at high temperatures, the organothiol small-molecule inhibitor undergoes thermal dissociation and is separated into ethyl, and the separated ethyl is adsorbed and bound to the surface of the silicon dioxide (SiO₂) substrate.

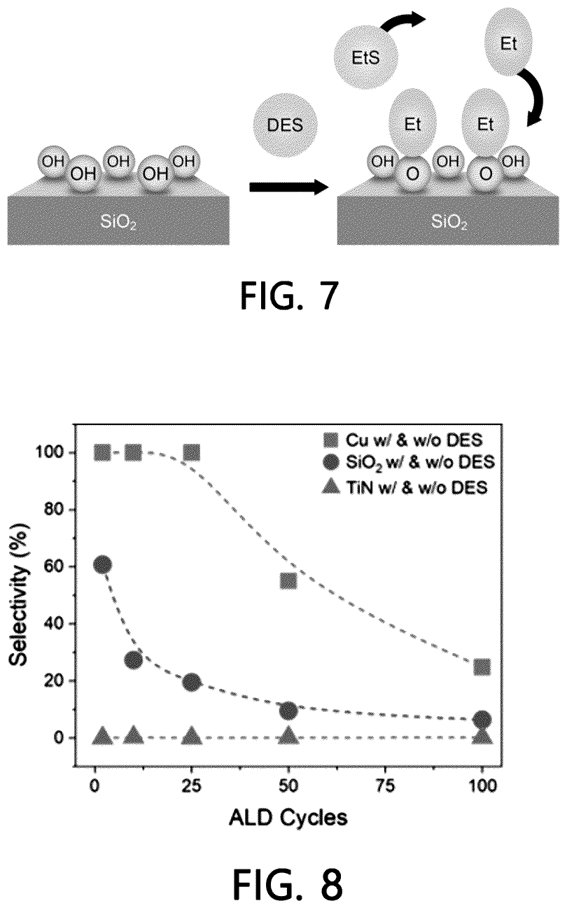

Meanwhile, FIG. 7 shows the adsorption mechanism of an organothiol small-molecule inhibitor (DES) on the surface of a silicon dioxide (SiO₂) substrate, and when the silicon dioxide (SiO₂) substrate is exposed to the organothiol small-molecule inhibitor while maintaining the internal temperature of a high-temperature chamber at 400° C., it may show a mechanism in which the organothiol small-molecule inhibitor (DES) undergoes thermal dissociation into ethylsulfanyl (EtS) and ethyl (Et), and the dissociated ethyl (Et) is adsorbed to —OH that is present on the surface of the silicon dioxide (SiO₂) substrate.

### Example 1: Formation of Hafnium Oxide (HfO₂) Thin Film on Copper (Cu) Substrate Exposed to Organothiol Small-Molecule Inhibitor

By using area selective atomic layer deposition (AS-ALD), a hafnium oxide (HfO₂) thin film was formed on a copper (Cu) substrate exposed to an organothiol small-molecule inhibitor for 30 seconds while maintaining the internal temperature of the chamber at 400° C. in Preparation Example 1. In this case, in terms of performing the area-selective atomic layer deposition, a compound represented by Chemical Formula 2-1 below was used as a precursor for thin-film deposition, and deionized water was used as a counter reactant.

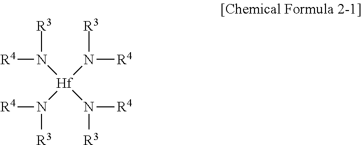

In Chemical Formula 2-1, R³ and R⁴ are methyl groups.

Specifically, a stainless-steel canister that maintained an internal temperature of 50° C. and stored a precursor for thin-film deposition, and a glass canister that maintained an internal temperature of 22° C. and stored a counter reactant were respectively connected to a chamber including a copper (Cu) substrate, and the area-selective atomic layer deposition was performed with the copper (Cu) substrate heated to 275° C. In addition, the area-selective atomic layer deposition used nitrogen gas (N₂ gas) at a flow rate of 10 sccm for purging, and was controlled by a mass flow controller (MFC).

Meanwhile, the area-selective atomic layer deposition was performed as a cycle of introducing the precursor for thin-film deposition into the chamber including the copper (Cu) substrate, exposing for 4 seconds, then purging for 60 seconds, and introducing the counter reactant into the chamber including the copper (Cu) substrate, exposing for 2 seconds, and then purging for 60 seconds.

In addition, the area-selective atomic layer deposition was performed for 2, 10, 25, 50 and 100 cycles, respectively.

### Example 2: Formation of Hafnium Oxide (HfO₂) Thin Film on Silicon Dioxide (SiO₂) Substrate Exposed to Organothiol Small-Molecule Inhibitor

By using area selective atomic layer deposition (AS-ALD), a hafnium oxide (HfO₂) thin film was formed on a silicon dioxide (SiO₂) substrate exposed to the organothiol small-molecule inhibitor for 30 seconds while maintaining the internal temperature of the chamber at 400° C. in Preparation Example 2. In this case, in terms of performing the area-selective atomic layer deposition, a compound represented by Chemical Formula 2-1 below was used as a precursor for thin-film deposition, and deionized water was used as a counter reactant.

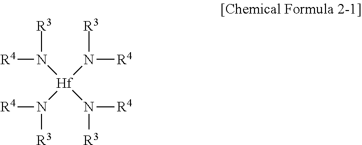

In Chemical Formula 2-1, R³ and R⁴ are methyl groups.

Specifically, a stainless-steel canister that maintained an internal temperature of 50° C. and stored a precursor for thin-film deposition, and a glass canister that maintained an internal temperature of 22° C. and stored a counter reactant were respectively connected to a chamber including a silicon dioxide (SiO₂) substrate, and the area-selective atomic layer deposition was performed with the silicon dioxide (SiO₂) substrate heated to 275° C. In addition, the area-selective atomic layer deposition used nitrogen gas (N₂ gas) at a flow rate of 10 sccm for purging, and was controlled by a mass flow controller (MFC).

Meanwhile, the area-selective atomic layer deposition was performed as a cycle of introducing the precursor for thin-film deposition into the chamber including the silicon dioxide (SiO₂) substrate, exposing for 4 seconds, then purging for 60 seconds, and introducing the counter reactant into the chamber including the silicon dioxide (SiO₂) substrate, exposing for 2 seconds, and then purging for 60 seconds.

In addition, the area-selective atomic layer deposition was performed for 2, 10, 25, 50 and 100 cycles, respectively.

### Example 3: Formation of Hafnium Oxide (HfO₂) Thin Film on Titanium Nitride (TiN) Substrate Exposed to Organothiol Small-Molecule Inhibitor

By using area selective atomic layer deposition (AS-ALD), a hafnium oxide (HfO₂) thin film was formed on a titanium nitride (TiN) substrate exposed to the organothiol small-molecule inhibitor for 30 seconds while maintaining the internal temperature of the chamber at 400° C. in Preparation Example 2. In this case, in terms of performing the area-selective atomic layer deposition, a compound represented by Chemical Formula 2-1 below was used as a precursor for thin-film deposition, and deionized water was used as a counter reactant.

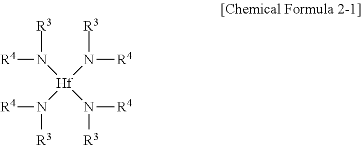

In Chemical Formula 2-1, R³ and R⁴ are methyl groups.

Specifically, a stainless-steel canister that maintained an internal temperature of 50° C. and stored a precursor for thin-film deposition, and a glass canister that maintained an internal temperature of 22° C. and stored a counter reactant were respectively connected to a chamber including a titanium nitride (TiN) substrate, and the area-selective atomic layer deposition was performed with the titanium nitride (TiN) substrate heated to 275° C. In addition, the area-selective atomic layer deposition used nitrogen gas (N₂ gas) at a flow rate of 10 sccm for purging, and was controlled by a mass flow controller (MFC).

Meanwhile, the area-selective atomic layer deposition was performed as a cycle of introducing the precursor for thin-film deposition into the chamber including the titanium nitride (TiN) substrate, exposing for 4 seconds, then purging for 60 seconds, and introducing the counter reactant into the chamber including the titanium nitride (TiN) substrate, exposing for 2 seconds, and then purging for 60 seconds.

In addition, the area-selective atomic layer deposition was performed for 2, 10, 25, 50 and 100 cycles, respectively.

### Comparative Example 1: Formation of Hafnium Oxide (HfO₂) Thin Film on Copper (Cu) Substrate

By using area selective atomic layer deposition (AS-ALD), a hafnium oxide (HfO₂) thin film was formed on a copper (Cu) substrate. In this case, in terms of performing the area-selective atomic layer deposition, a compound represented by Chemical Formula 2-1 below was used as a precursor for thin-film deposition, and deionized water was used as a counter reactant.

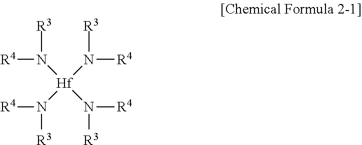

In Chemical Formula 2-1, R³ and R⁴ are methyl groups.

Specifically, a stainless-steel canister that maintained an internal temperature of 50° C. and stored a precursor for thin-film deposition, and a glass canister that maintained an internal temperature of 22° C. and stored a counter reactant were respectively connected to a chamber including a copper (Cu) substrate, and the area-selective atomic layer deposition was performed with the copper (Cu) substrate heated to 275° C. In addition, the area-selective atomic layer deposition used nitrogen gas (N2 gas) at a flow rate of 10 sccm for purging, and was controlled by a mass flow controller (MFC).

Meanwhile, the area-selective atomic layer deposition was performed as a cycle of introducing the precursor for thin-film deposition into the chamber including the copper (Cu) substrate, exposing for 4 seconds, then purging for 60 seconds, and introducing the counter reactant into the chamber including the copper (Cu) substrate, exposing for 2 seconds, and then purging for 60 seconds.

In addition, the area-selective atomic layer deposition was performed for 2, 10, 25, 50 and 100 cycles, respectively.

### Comparative Example 2: Formation of Hafnium Oxide (HfO₂) Thin Film on Silicon Dioxide (SiO₂) Substrate

By using area selective atomic layer deposition (AS-ALD), a hafnium oxide (HfO₂) thin film was formed on a silicon dioxide (SiO₂) substrate. In this case, in terms of performing the area-selective atomic layer deposition, a compound represented by Chemical Formula 2-1 was used as a precursor for thin-film deposition, and deionized water was used as a counter reactant.

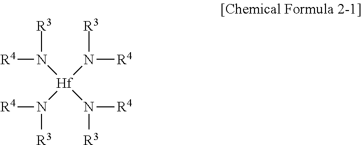

In Chemical Formula 2-1, R³ and R⁴ are methyl groups.

Specifically, a stainless-steel canister that maintained an internal temperature of 50° C. and stored a precursor for thin-film deposition, and a glass canister that maintained an internal temperature of 22° C. and stored a counter reactant were respectively connected to a chamber including a silicon dioxide (SiO₂) substrate, and the area-selective atomic layer deposition was performed with the silicon dioxide (SiO₂) substrate heated to 275° C. In addition, the area-selective atomic layer deposition used nitrogen gas (N2 gas) at a flow rate of 10 sccm for purging, and was controlled by a mass flow controller (MFC).

Meanwhile, the area-selective atomic layer deposition was performed as a cycle of introducing the precursor for thin-film deposition into the chamber including the silicon dioxide (SiO₂) substrate, exposing for 4 seconds, then purging for 60 seconds, and introducing the counter reactant into the chamber including the silicon dioxide (SiO₂) substrate, exposing for 2 seconds, and then purging for 60 seconds.

In addition, the area-selective atomic layer deposition was performed for 2, 10, 25, 50 and 100 cycles, respectively.

### Comparative Example 3: Formation of Hafnium Oxide (HfO₂) Thin Film on Titanium Nitride (TiN) Substrate

By using area selective atomic layer deposition (AS-ALD), a hafnium oxide (HfO₂) thin film was formed on a titanium nitride (TiN) substrate. In this case, in terms of performing the area-selective atomic layer deposition, a compound represented by Chemical Formula 2-1 was used as a precursor for thin-film deposition, and deionized water was used as a counter reactant.

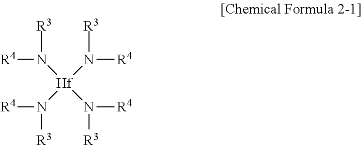

In Chemical Formula 2-1, R³ and R⁴ are methyl groups.

Specifically, a stainless-steel canister that maintained an internal temperature of 50° C. and stored a precursor for thin-film deposition, and a glass canister that maintained an internal temperature of 22° C. and stored a counter reactant were respectively connected to a chamber including a titanium nitride (TiN) substrate, and the area-selective atomic layer deposition was performed with the titanium nitride (TiN) substrate heated to 275° C. In addition, the area-selective atomic layer deposition used nitrogen gas (N2 gas) at a flow rate of 10 sccm for purging, and was controlled by a mass flow controller (MFC).

Meanwhile, the area-selective atomic layer deposition was performed as a cycle of introducing the precursor for thin-film deposition into the chamber including the titanium nitride (TiN) substrate, exposing for 4 seconds, then purging for 60 seconds, and introducing the counter reactant into the chamber including the titanium nitride (TiN) substrate, exposing for 2 seconds, and then purging for 60 seconds.

In addition, the area-selective atomic layer deposition was performed for 2, 10, 25, 50 and 100 cycles, respectively.

### Experimental Example 4: Selectivity Measurement According to the Number of Cycles of Area-Selective Atomic Layer Deposition

Selectivity was calculated by using Equation 1 below based on a difference in atomic concentrations between the growth area (GS) and the non-growth area (NGS).

$$Selectivity ( \% ) = \frac{{∅}_{GS} - {∅}_{NGS}}{{∅}_{GS} + {∅}_{NGS}} \times 100 \qquad [ Equation 1 ]$$

In Equation 1 above, Ø represents the atomic concentration.

The homogeneous selectivity according to the number of cycles of area-selective atomic layer deposition between the copper (Cu) substrate having a hafnium oxide (HfO₂) thin film formed thereon in Comparative Example 1 and the copper (Cu) substrate having a hafnium oxide (HfO₂) thin film formed thereon in Example 1 was measured, and the results are shown in FIG. 8 (=indicated as Cu w/& w/o DES).

As can be confirmed in FIG. 8, the homogeneous selectivity of a copper (Cu) substrate surface forming a hafnium oxide (HfO₂) thin film on the substrate was measured to be 100% in 2 cycles, 99.8% in 10 cycles, 98% in 25 cycles, 55% in 50 cycles and 24.8% in 100 cycles.

In addition, the homogeneous selectivity according to the number of cycles of area-selective atomic layer deposition between the silicon dioxide (SiO₂) substrate having a hafnium oxide (HfO₂) thin film formed thereon in Comparative Example 2 and the silicon dioxide (SiO₂) substrate having a hafnium oxide (HfO₂) thin film formed thereon in Example 2 was measured, and the results are shown in FIG. 8 (=indicated as SiO₂ w/& w/o DES).

In addition, the homogeneous selectivity according to the number of cycles of area-selective atomic layer deposition between the titanium nitride (TiN) substrate having a hafnium oxide (HfO₂) thin film formed thereon in Comparative Example 3 and the titanium nitride (TiN) substrate having a hafnium oxide (HfO₂) thin film formed thereon in Example 3 was measured, and the results are shown in FIG. 8 (indicated as TiN w/& w/o DES).

As can be confirmed in FIG. 8, the homogeneous selectivity of the silicon dioxide (SiO₂) substrate surface forming a hafnium oxide (HfO₂) thin film on the substrate was measured to be 61% in 2 cycles, 27% in 10 cycles, 19% in 25 cycles, 9% in 50 cycles and 6% in 100 cycles.

In addition, it was confirmed that homogeneous selectivity did not occur between the titanium nitride (TiN) substrate having a hafnium oxide (HfO₂) film formed thereon in Comparative Example 3 and the titanium nitride (TiN) substrate having a hafnium oxide (HfO₂) film formed thereon in Example 3.

From these results, it was confirmed that the homogeneous selectivity decreased as the number of cycles of area-selective atomic layer deposition increased on both of a copper (Cu) substrate surface having a hafnium oxide (HfO₂) film formed thereon and a silicon dioxide (SiO₂) substrate surface having a hafnium oxide (HfO₂) film formed thereon.

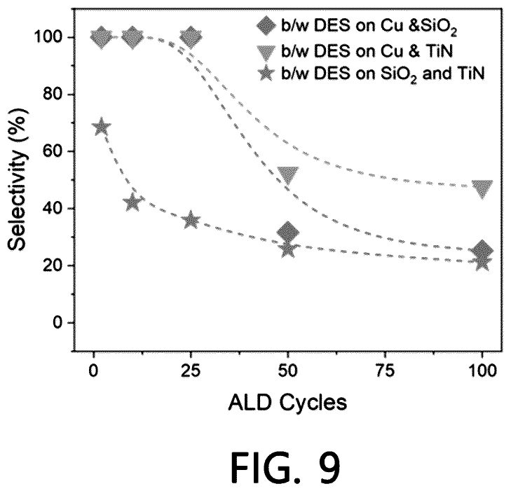

Meanwhile, the heterogeneous selectivity according to the number of cycles of area-selective atomic layer deposition between the copper (Cu) substrate having a hafnium oxide (HfO₂) film formed thereon in Example 1 and the silicon dioxide (SiO₂) substrate having a hafnium oxide (HfO₂) film formed thereon in Example 2 was measured, and the results are shown in FIG. 9 (=indicated as b/w DES on Cu & SiO₂).

In addition, the heterogeneous selectivity according to the number of cycles of area-selective atomic layer deposition between the silicon dioxide (SiO₂) substrate having a hafnium oxide (HfO₂) film formed thereon in Example 2 and the titanium nitride (TiN) substrate having a hafnium oxide (HfO₂) film formed thereon in Example 3 was measured, and the results are shown in FIG. 9 (=indicated as b/w DES on Cu & TiN).

In addition, the heterogeneous selectivity according to the number of cycles of area-selective atomic layer deposition between the titanium nitride (TiN) substrate having a hafnium oxide (HfO₂) film formed thereon in Example 3 and the copper (Cu) substrate having a hafnium oxide (HfO₂) film formed thereon in Example 1 was measured, and the results are shown in FIG. 9 (=indicated as b/w DES on SiO₂ & TiN).

As can be confirmed in FIG. 9, the heterogeneous selectivity according to the number of cycles of the area-selective atomic layer deposition between a copper (Cu) substrate forming a hafnium oxide (HfO₂) thin film on the substrate in Example 1 and a silicon dioxide (SiO₂) substrate forming a hafnium oxide (HfO₂) thin film on the substrate in Example 2 was measured to be 100% from the 2^{nd} cycle to the 25^{th} cycle, 52.4% for 50 cycles, and 47.6% for 100 cycles.

In addition, the heterogeneous selectivity according to the number of cycles of the area-selective atomic layer deposition between a silicon dioxide (SiO₂) substrate forming a hafnium oxide (HfO₂) thin film on the substrate in Example 2 and a titanium nitride (TiN) substrate forming a hafnium oxide (HfO₂) thin film on the substrate in Example 3 was measured to be 100% for 2 cycles, 99.2% for 10 cycles, 98.1% for 25 cycles, 31.7% for 50 cycles, and 25.2% for 100 cycles.

In addition, the heterogeneous selectivity according to the number of cycles of area-selective atomic layer deposition between a titanium nitride (TiN) substrate forming a hafnium oxide (HfO₂) thin film on the substrate in Example 3 and a copper (Cu) substrate forming a hafnium oxide (HfO₂) thin film on the substrate in Example 1 was measured to be 68.5% for 2 cycles, 42.1% for 10 cycles, 35.9% for 25 cycles, 25.8% for 50 cycles, and 21.2% for 100 cycles.

### Experimental Example 5: Measurement of Thickness of Hafnium Oxide (HfO₂) Thin Film According to the Number of Cycles of Area-Selective Atomic Layer Deposition

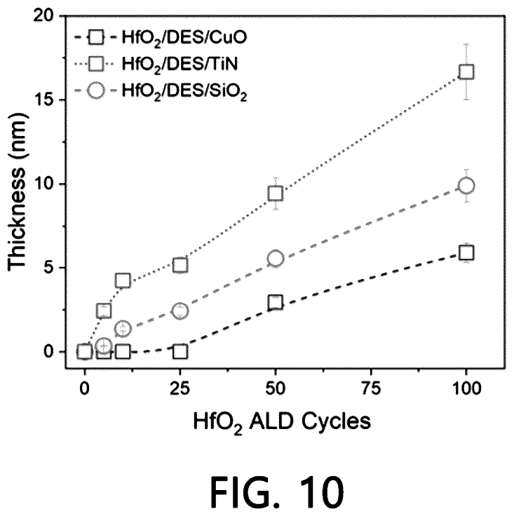

According to the number of cycles of area-selective atomic layer deposition, the thickness of the hafnium oxide (HfO₂) thin film formed on the copper (Cu) substrate in Example 1 (indicated as =HfO₂/DES/CuO), the thickness of the hafnium oxide (HfO₂) thin film formed the silicon dioxide (SiO₂) in Example 2 (indicated as =HfO₂/DES/SiO₂), and the thickness of the hafnium oxide (HfO₂) thin film formed on the titanium nitride (TiN) substrate in Example 3 (indicated as =HfO₂/DES/TiN) were respectively measured, and the results are shown in FIG. 10.

As can be confirmed in FIG. 10, the formation of a hafnium oxide (HfO₂) thin film on a copper (Cu) substrate was delayed until 25 cycles, and the formation of a hafnium oxide (HfO₂) thin film could be observed beyond 25 cycles. Through these results, it was confirmed that the formation of a hafnium oxide (HfO₂) thin film is delayed up to 25 cycles by the organothiol small-molecule inhibitor adsorbed on the surface of the copper (Cu) substrate, and this delay effect is lost after 25 cycles.

Meanwhile, a delay phenomenon in the formation of the hafnium oxide (HfO₂) thin film that occurs on the copper (Cu) substrate was not observed for the silicon dioxide (SiO₂) and titanium nitride (TiN) substrates, and such a hafnium oxide (HfO₂) thin film delay effect was observed to be most excellent on the copper (Cu) substrate, followed by the silicon dioxide (SiO₂) substrate and the titanium nitride (TiN) substrate. In particular, the delay effect of the formation of a hafnium oxide (HfO₂) thin film was not observed on the titanium nitride (TiN) substrate.

Specifically, in Example 1, the thickness of the hafnium oxide (HfO₂) thin film formed on the copper (Cu) substrate was measured to be 0 nm for 2 cycles, 0 nm for 10 cycles, 0 nm for 25 cycles, 2.95 nm for 50 cycles, and 5.91 nm for 100 cycles.

Additionally, in Example 2, the thickness of the hafnium oxide (HfO₂) thin film formed on the silicon dioxide (SiO₂) substrate was measured to be 0.35 nm for 2 cycles, 1.37 nm for 10 cycles, 2.43 nm for 25 cycles, 5.56 nm for 50 cycles, and 9.90 nm for 100 cycles.

Additionally, in Example 3, the thickness of the hafnium oxide (HfO₂) thin film formed on the titanium nitride (TiN) substrate was measured to be 2.43 nm for 2 cycles, 4.25 nm for 10 cycles, 5.16 nm for 25 cycles, 9.43 nm for 50 cycles, and 16.66 nm for 100 cycles.

### Preparation Example 1: Formation of Hafnium Oxide (HfO₂) Thin Film on Titanium Nitride (TiN) Substrate Having Silicon Dioxide (SiO₂) Pattern Formed Thereon

(1) A silicon dioxide (SiO₂) pattern was formed on a titanium nitride (TiN) substrate using the drop casting method. In this case, the silicon dioxide (SiO₂) pattern was formed using a 0.1 M solution in which silicon dioxide (SiO₂) powder was dispersed in 50 mL of ethanol, and the solution remaining after the silicon dioxide (SiO₂) pattern formation was vaporized at 22° C.
(2) The titanium nitride (TiN) substrate having the silicon dioxide (SiO₂) pattern formed thereon was ultrasonically cleaned for 10 minutes sequentially with acetone, isopropyl alcohol and deionized water.
(3) After drying the cleaned titanium nitride (TiN) substrate having the silicon dioxide (SiO₂) pattern formed thereon with nitrogen gas (N₂ gas), it was introduced into a chamber having an internal temperature of 400° C. and a vacuum base pressure, and it was maintained for 10 minutes.
(4) A stainless-steel canister that maintained an internal temperature of 25° C. and stored an organothiol small-molecule inhibitor was prepared. In this case, a compound represented by Chemical Formula 1 below was used as the organothiol small-molecule inhibitor.

R¹—S—R² [Chemical Formula 1]

In Chemical Formula 1, R¹ and R² are ethyl groups.
(5) The stainless-steel canister and the substrate were connected such that the titanium nitride (TiN) substrate having the silicon dioxide (SiO₂) pattern formed thereon could be exposed to the compound represented by Chemical Formula 1.
(6) The chamber was purged using nitrogen gas (N₂ gas), and while maintaining the internal temperature of the chamber at 400° C., the titanium nitride (TiN) substrate having the silicon dioxide (SiO₂) pattern formed thereon was exposed to the compound represented by Chemical Formula 1 above for 30 seconds.
(7) The titanium nitride (TiN) substrate having the silicon dioxide (SiO₂) pattern formed thereon that was exposed to the compound represented by Chemical Formula 1 above was cooled to a temperature of 25° C.
(8) By using area-selective atomic layer deposition (AS-ALD), a hafnium oxide (HfO₂) thin film was formed on the titanium nitride (TiN) substrate having the silicon dioxide (SiO₂) pattern formed thereon that was exposed to the organic thiol small molecule inhibitor. In this case, when performing the area-selective atomic layer deposition, a compound represented by Chemical Formula 2-1 below was used as a precursor for thin-film deposition, and deionized water was used as a counter reactant.

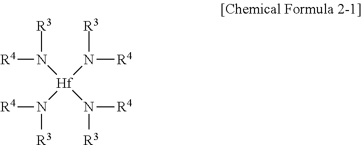

In Chemical Formula 2-1, R³ and R⁴ are methyl groups.

Specifically, a stainless-steel canister that maintained an internal temperature of 50° C. and stored a precursor for thin-film deposition, and a glass canister that maintained an internal temperature of 22° C. and stored a counter reactant were respectively connected to a chamber including a titanium nitride (TiN) substrate having a silicon dioxide (SiO₂) pattern formed thereon, and the area-selective atomic layer deposition was performed with the titanium nitride (TiN) substrate having a silicon dioxide (SiO₂) pattern formed thereon heated to 275° C. In addition, the area-selective atomic layer deposition used nitrogen gas (N2 gas) at a flow rate of 10 sccm for purging, and was controlled by a mass flow controller (MFC).

Meanwhile, the area-selective atomic layer deposition was performed as a cycle of introducing the precursor for thin-film deposition into the chamber including the titanium nitride (TiN) substrate having a silicon dioxide (SiO₂) pattern formed thereon, exposing for 4 seconds, then purging for 60 seconds, and introducing the counter reactant into the chamber including the titanium nitride (TiN) substrate having a silicon dioxide (SiO₂) pattern formed thereon, exposing for 2 seconds, and then purging for 60 seconds. In addition, the area-selective atomic layer deposition was performed for 10 cycles.

### Preparation Example 2: Formation of Hafnium Oxide (HfO₂) Thin Film on Titanium Nitride (TiN) Substrate Having Copper (Cu) Pattern Formed Thereon

(1) A copper (Cu) pattern was formed on a titanium nitride (TiN) substrate using the drop casting method. In this case, the copper (Cu) pattern was formed using a 0.1M solution of copper (Cu) powder dispersed in 50 mL of ethanol, and the solution remaining after the copper (Cu) pattern was formed was vaporized at 22° C.
(2) The titanium nitride (TiN) substrate having the copper (Cu) pattern formed thereon was ultrasonically cleaned for 10 minutes sequentially with acetone, isopropyl alcohol and deionized water.
(3) After drying the cleaned titanium nitride (TiN) substrate having the copper (Cu) pattern formed thereon with nitrogen gas (N₂ gas), it was introduced into a chamber having an internal temperature of 400° C. and a vacuum base pressure, and it was maintained for 10 minutes.
(4) A stainless-steel canister that maintained an internal temperature of 25° C. and stored an organothiol small-molecule inhibitor was prepared. In this case, a compound represented by Chemical Formula 1 was used as the organothiol small-molecule inhibitor.

R¹—S—R² [Chemical Formula 1]

In Chemical Formula 1, R¹ and R² are ethyl groups.
(5) The stainless-steel canister and the substrate were connected such that the titanium nitride (TiN) substrate having the copper (Cu) pattern formed thereon could be exposed to the compound represented by Chemical Formula 1 above.
(6) The chamber was purged using nitrogen gas (N₂ gas), and while the internal temperature of the chamber was maintained at 400° C., the titanium nitride (TiN) substrate having the copper (Cu) pattern formed thereon was exposed to the compound represented by Chemical Formula 1 above for 30 seconds.
(7) The titanium nitride (TiN) substrate having the copper (Cu) pattern formed thereon that was exposed to the compound represented by Chemical Formula 1 above was cooled to a temperature of 25° C.
(8) By using area-selective atomic layer deposition (AS-ALD), a hafnium oxide (HfO₂) thin film was formed on the titanium nitride (TiN) substrate having the copper (Cu) pattern formed thereon that was exposed to the organic thiol small molecule inhibitor. In this case, when performing the area-selective atomic layer deposition, a compound represented by Chemical Formula 2-1 below was used as a precursor for thin-film deposition, and deionized water was used as a counter reactant.

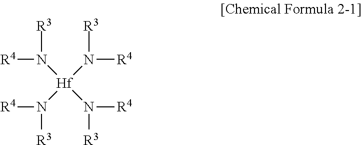

In Chemical Formula 2-1, R³ and R⁴ are methyl groups.

Specifically, a stainless-steel canister that maintained an internal temperature of 50° C. and stored a precursor for thin-film deposition, and a glass canister that maintained an internal temperature of 22° C. and stored a counter reactant were respectively connected to a chamber including the titanium nitride (TiN) substrate having the copper (Cu) pattern formed thereon, and the area-selective atomic layer deposition was performed with the titanium nitride (TiN) substrate having the copper (Cu) pattern heated to 275° C. In addition, the area-selective atomic layer deposition used nitrogen gas (N₂ gas) at a flow rate of 10 sccm for purging, and was controlled by a mass flow controller (MFC).

Meanwhile, the area-selective atomic layer deposition was performed as a cycle of introducing the precursor for thin-film deposition into the chamber including the titanium nitride (TiN) substrate having the copper (Cu) pattern formed thereon, exposing for 4 seconds, then purging for 60 seconds, and introducing the counter reactant into the chamber including the titanium nitride (TiN) substrate having the copper (Cu) pattern formed thereon, exposing for 2 seconds, and then purging for 60 seconds. In addition, the area-selective atomic layer deposition was performed for 10 cycles.

### Comparative Preparation Example 1: Formation of Hafnium Oxide (HfO₂) Thin Film on Titanium Nitride (TiN) Substrate Having Silicon Dioxide (SiO₂) Pattern Formed Thereon

(1) A silicon dioxide (SiO₂) pattern was formed on a titanium nitride (TiN) substrate by using the drop casting method. In this case, the silicon dioxide (SiO₂) pattern was formed using a 0.1 M solution in which silicon dioxide (SiO₂) powder was dispersed in 50 mL of ethanol, and the solution remaining after the silicon dioxide (SiO₂) pattern formation was vaporized at 22° C.
(2) The titanium nitride (TiN) substrate having the silicon dioxide (SiO₂) pattern formed thereon was ultrasonically cleaned for 10 minutes sequentially with acetone, isopropyl alcohol and deionized water.
(3) The cleaned titanium nitride (TiN) substrate having the silicon dioxide (SiO₂) pattern formed thereon was dried with nitrogen gas (N₂ gas), then introduced into a chamber with an internal temperature of 25° C. and maintained for 10 minutes.
(4) By using area selective atomic layer deposition (AS-ALD), a hafnium oxide (HfO₂) thin film was formed on the titanium nitride (TiN) substrate having the silicon dioxide (SiO₂) pattern formed thereon. In this case, in terms of performing the area-selective atomic layer deposition, a compound represented by Chemical Formula 2-1 was used as a precursor for thin-film deposition, and deionized water was used as a counter reactant.

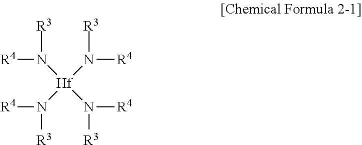

In Chemical Formula 2-1 above, R³ and R⁴ are methyl groups.

Specifically, a stainless-steel canister that maintained an internal temperature of 50° C. and stored a precursor for thin-film deposition, and a glass canister that maintained an internal temperature of 22° C. and stored a counter reactant were respectively connected to a chamber including the titanium nitride (TiN) substrate having the silicon dioxide (SiO₂) pattern formed thereon, and the area-selective atomic layer deposition was performed with the titanium nitride (TiN) substrate having the silicon dioxide (SiO₂) pattern formed thereon heated to 275° C. In addition, the area-selective atomic layer deposition used nitrogen gas (N2 gas) at a flow rate of 10 sccm for purging, and was controlled by a mass flow controller (MFC).

Meanwhile, the area-selective atomic layer deposition was performed as a cycle of introducing the precursor for thin-film deposition into the chamber including the titanium nitride (TiN) substrate having the silicon dioxide (SiO₂) pattern formed thereon, exposing for 4 seconds, then purging for 60 seconds, and introducing the counter reactant into the chamber including the titanium nitride (TiN) substrate having the silicon dioxide (SiO₂) pattern formed thereon, exposing for 2 seconds, and then purging for 60 seconds. In addition, the area-selective atomic layer deposition was performed for 10 cycles.

### Comparative Preparation Example 2: Formation of Hafnium Oxide (HfO₂) Thin Film on Titanium Nitride (TiN) Substrate Having Copper (Cu) Pattern Formed Thereon

(1) A copper (Cu) pattern was formed on a titanium nitride (TiN) substrate by using the drop casting method. In this case, the copper (Cu) pattern was formed using a 0.1 M solution in which copper (Cu) powder was dispersed in 50 mL of ethanol, and the solution remaining after the copper (Cu) pattern formation was vaporized at 22° C.
(2) The titanium nitride (TiN) substrate having the copper (Cu) pattern formed thereon was ultrasonically cleaned for 10 minutes sequentially with acetone, isopropyl alcohol and deionized water.
(3) The cleaned titanium nitride (TiN) substrate having the copper (Cu) pattern formed thereon was dried with nitrogen gas (N₂ gas), then introduced into a chamber with an internal temperature of 25° C. and maintained for 10 minutes.
(4) By using area selective atomic layer deposition (AS-ALD), a hafnium oxide (HfO₂) thin film was formed on the titanium nitride (TiN) substrate having the copper (Cu) pattern formed thereon. In this case, in terms of performing the area-selective atomic layer deposition, a compound represented by Chemical Formula 2-1 was used as a precursor for thin-film deposition, and deionized water was used as a counter reactant.

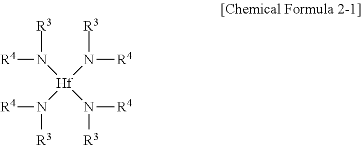

Chemical In Formula 2-1, R³ and R⁴ are methyl groups.

Specifically, a stainless-steel canister that maintained an internal temperature of 50° C. and stored a precursor for thin-film deposition, and a glass canister that maintained an internal temperature of 22° C. and stored a counter reactant were respectively connected to a chamber including the titanium nitride (TiN) substrate having the copper (Cu) pattern formed thereon, and the area-selective atomic layer deposition was performed with the titanium nitride (TiN) substrate having the copper (Cu) pattern formed thereon heated to 275° C. In addition, the area-selective atomic layer deposition used nitrogen gas (N₂ gas) at a flow rate of 10 sccm for purging, and was controlled by a mass flow controller (MFC).

Meanwhile, the area-selective atomic layer deposition was performed as a cycle of introducing the precursor for thin-film deposition into the chamber including the titanium nitride (TiN) substrate having the copper (Cu) pattern formed thereon, exposing for 4 seconds, then purging for 60 seconds, and introducing the counter reactant into the chamber including the titanium nitride (TiN) substrate having the copper (Cu) pattern formed thereon, exposing for 2 seconds, and then purging for 60 seconds. In addition, the area-selective atomic layer deposition was performed for 10 cycles.

### Experimental Example 6: FE-SEM Analysis

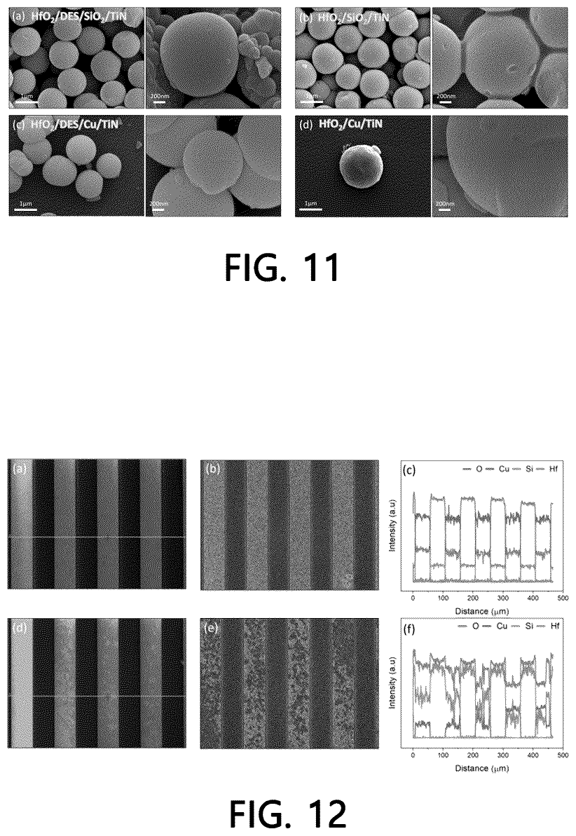

An analysis using field-emission scanning electron microscopy (FE-SEM) was performed on the titanium nitride (TiN) substrate having a silicon dioxide (SiO₂) pattern formed thereon in Preparation Example 1, and the results are shown in (a) of FIG. 11. In addition, an analysis using field-emission scanning electron microscopy was performed on the titanium nitride (TiN) substrate having a silicon dioxide (SiO₂) pattern formed thereon in Comparative Preparation Example 1, and the results are shown in (b) of FIG. 11. In addition, an analysis using field emission scanning electron microscopy was performed on the titanium nitride (TiN) substrate having a copper (Cu) pattern formed thereon in Preparation Example 2, and the results are shown in (c) of FIG. 11. In addition, an analysis using field emission scanning electron microscopy was performed on the titanium nitride (TiN) substrate having a copper (Cu) pattern formed thereon in Comparative Preparation Example 2, and the results are shown in (d) of FIG. 11. As analysis equipment, JEOL JSM-7800F equipment (JEOL Ltd.) was used.

As can be confirmed by comparing (a) of FIG. 11 and (b) of FIG. 11, it was confirmed that in the titanium nitride (TiN) substrate having the silicon dioxide (SiO₂) pattern formed thereon Comparative Preparation Example 1, the roughness of the silicon dioxide (SiO₂) particles was greater than the roughness of the silicon dioxide (SiO₂) particles in the titanium nitride (TiN) substrate having the silicon dioxide (SiO₂) pattern formed thereon in Preparation Example 1, and through this, it was confirmed that the hafnium oxide (HfO₂) thin film was formed to be thicker on the surface of the titanium nitride (TiN) substrate having the silicon dioxide (SiO₂) pattern formed thereon in Comparative Preparation Example 1.

In addition, as can be confirmed by comparing (c) of FIG. 11 and (d) of FIG. 11, it was confirmed that in the titanium nitride (TiN) substrate having the copper (Cu) pattern formed thereon Comparative Preparation Example 2, the roughness of the copper (Cu) particles was greater than the roughness of the copper (Cu) particles in the titanium nitride (TiN) substrate having the copper (Cu) pattern formed thereon in Preparation Example 2, and through this, it was confirmed that the hafnium oxide (HfO₂) thin film was formed to be thicker on the surface of the titanium nitride (TiN) substrate having the copper (Cu) pattern formed thereon in Comparative Preparation Example 2. In addition, it was confirmed that the formation of a hafnium oxide (HfO₂) thin film was suppressed by the adsorbed organothiol small-molecule inhibitor on the titanium nitride (TiN) substrate having the copper (Cu) pattern formed thereon in Preparation Example 2.

### Preparation Example 3: Formation of Hafnium Oxide (HfO₂) Thin Film on Titanium Nitride (TiN) Substrate Having Silicon Dioxide (SiO₂)-Copper (Cu) Pattern Formed Thereon

(1) A silicon dioxide (SiO₂)-copper (Cu) pattern was formed on a titanium nitride (TiN) substrate using a drop casting method. In this case, the silicon dioxide (SiO₂)-copper (Cu) pattern was formed using a 0.1 M solution in which silicon dioxide (SiO₂) powder and copper (Cu) powder were dispersed in 50 mL of ethanol, and the solution remaining after the silicon dioxide (SiO₂)-copper (Cu) pattern formation was vaporized at 22° C.
(2) A titanium nitride (TiN) substrate having a silicon dioxide (SiO₂)-copper (Cu) pattern formed thereon was ultrasonically cleaned sequentially in acetone, isopropyl alcohol and deionized water for 10 minutes.
(3) After drying the cleaned titanium nitride (TiN) substrate having the silicon dioxide (SiO₂)-copper (Cu) pattern formed thereon with nitrogen gas (N₂ gas), it was introduced into a chamber having an internal temperature of 400° C. and a vacuum base pressure condition and maintained for 10 minutes.
(4) A stainless-steel canister that maintained an internal temperature of 25° C. and stored an organothiol small-molecule inhibitor was prepared. In this case, a compound represented by Chemical Formula 1 below was used as the organothiol small-molecule inhibitor.

R¹—S—R² [Chemical Formula 1]

In Chemical Formula 1, R¹ and R² are ethyl groups.
(5) The stainless-steel canister and the substrate were connected such that the titanium nitride (TiN) substrate having the silicon dioxide (SiO₂)-copper (Cu) pattern formed thereon could be exposed to the compound represented by Chemical Formula 1 above.
(6) The chamber was purged with nitrogen gas (N₂ gas), and while the internal temperature of the chamber was maintained at 400° C., the titanium nitride (TiN) substrate having the silicon dioxide (SiO₂)-copper (Cu) pattern formed thereon was exposed to the compound represented by Chemical Formula 1 for 30 seconds.
(7) The titanium nitride (TiN) substrate having the silicon dioxide (SiO₂)-copper (Cu) pattern formed thereon and exposed to the compound represented by Chemical Formula 1 above was cooled to a temperature of 25° C.
(8) By using area-selective atomic layer deposition (AS-ALD), a hafnium oxide (HfO₂) thin film was formed on the titanium nitride (TiN) substrate having the silicon dioxide (SiO₂)-copper (Cu) pattern formed thereon and exposed to the organic thiol small molecule inhibitor. In this case, when performing the area-selective atomic layer deposition, a compound represented by Chemical Formula 2-1 below was used as a precursor for thin-film deposition, and deionized water was used as a counter reactant.

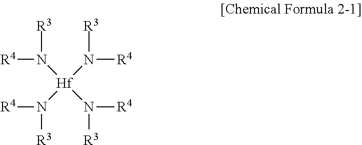

In Chemical Formula 2-1, R³ and R⁴ are methyl groups.

Specifically, a stainless-steel canister that maintained an internal temperature of 50° C. and stored a precursor for thin-film deposition, and a glass canister that maintained an internal temperature of 22° C. and stored a counter reactant were respectively connected to a chamber including the titanium nitride (TiN) substrate having the silicon dioxide (SiO₂)-copper (Cu) pattern formed thereon, and the area-selective atomic layer deposition was performed with the titanium nitride (TiN) substrate having silicon dioxide (SiO₂)-copper (Cu) pattern formed thereon heated to 275° C. In addition, the area-selective atomic layer deposition used nitrogen gas (N₂ gas) at a flow rate of 10 sccm for purging, and was controlled by a mass flow controller (MFC).

Meanwhile, the area-selective atomic layer deposition was performed as a cycle of introducing the precursor for thin-film deposition into the chamber including the titanium nitride (TiN) substrate having the silicon dioxide (SiO₂)-copper (Cu) pattern formed thereon, exposing for 4 seconds, then purging for 60 seconds, and introducing the counter reactant into the chamber including the titanium nitride (TiN) substrate having the silicon dioxide (SiO₂)-copper (Cu) pattern formed thereon, exposing for 2 seconds, and then purging for 60 seconds.

In addition, the area-selective atomic layer deposition was performed for 10 and 25 cycles, respectively.

### Experimental Example 7: AES Analysis

An analysis through Auger electron spectroscopy (AES) was performed on the titanium nitride (TiN) substrate having the silicon dioxide (SiO₂)-copper (Cu) pattern formed thereon in Preparation Example 3, and the results are shown in FIG. 12. As analysis equipment, PHI 700™ equipment (Scanning Auger Nanoprobe) was used, and the line scan and mapping method was based on a two-point scan with a beam size of 20 nm and an analysis area of 20×20 μm².
(a) and (d) of FIG. 12 are AES images of the silicon dioxide (SiO₂)-copper (Cu) patterns for a mapping profile and a line scan. In addition, (b) of FIG. 12 is a mapping profile after performing the area-selective atomic layer deposition for 10 cycles, and (e) of FIG. 12 is a mapping profile after performing the area-selective atomic layer deposition for 25 cycles. In addition, (c) of FIG. 12 is a line scan after the area-selective atomic layer deposition was performed for 10 cycles, and (f) of FIG. 12 is a line scan after the area-selective atomic layer deposition was performed for 25 cycles.
(b) of FIG. 12 shows a mapping profile with RGB overlay of red oxygen (O), green copper (Cu) and blue hafnium (Hf), and it can be seen that copper (Cu) patches are observed between purple patches. The purple patches represent oxygen (O) from silicon dioxide (SiO₂) and hafnium oxide (HfO₂) overlapping with the blue hafnium (Hf). This suggests that there is no hafnium oxide (HfO₂) on the copper (Cu) lines of the pattern, and through this result, it can be confirmed that complete blocking selectivity of copper (Cu) over silicon dioxide (SiO₂) was achieved after performing the area-selective atomic layer deposition for 10 cycles.
(c) of FIG. 12 shows a line scan for the same pattern, where the hafnium (Hf) concentration was not observed in the copper profile (Cu profile), but only the oxide profile was observed. In the silicon dioxide (SiO₂) line, since there were oxides included in silicon dioxide (SiO₂) and oxides included in hafnium oxide (HfO₂), a greater oxygen (O) intensity was observed in the silicon dioxide (SiO₂) line.

Meanwhile, in (e) and (f) of FIG. 12, hafnium (Hf) was observed in the copper (Cu) line. These results confirmed that the copper (Cu) line has hafnium (Hf) blocking properties and interferes with atomic layer deposition. In (e) of FIG. 12, a small patch of green can still be observed, which indicates that the small patch of copper (Cu) had not yet covered the hafnium oxide (HfO₂). In (f) of FIG. 12, it can be seen that hafnium (Hf) existed throughout the scanned area, but a higher concentration of hafnium (Hf) was still observed in the silicon dioxide (SiO₂) line.

In conclusion, through AES analysis, it was confirmed that the organothiol small-molecule inhibitor effectively blocks copper (Cu) up to 10 cycles of area-selective atomic layer deposition in the silicon dioxide (SiO₂)-copper (Cu) pattern.

1. A method for selectively depositing a thin film using area-selective atomic layer deposition, the method comprising:
step 1 of preparing a substrate on which a first substrate comprising a metal, a second substrate comprising silicon dioxide (SiO₂) and a third substrate comprising a nitride are arranged in parallel and integrated;
step 2 of exposing the substrate to an organothiol small-molecule inhibitor; and
step 3 of forming a thin film on a surface of a substrate exposed to the organothiol small-molecule inhibitor, by using area-selective atomic layer deposition (AS-ALD),
wherein the thickness of a thin film formed on a surface of the first substrate, the thickness of a thin film formed on a surface of the second substrate, and the thickness of a thin film formed on a surface of the third substrate are different.

2. The method of claim 1, wherein the metal is selected from the group consisting of copper (Cu), cobalt (Co), ruthenium (Ru), molybdenum (Mo) and tungsten (W),
wherein the nitride is selected from the group consisting of titanium nitride, molybdenum nitride, tungsten nitride and silicon nitride, and
wherein the thin film is a thin film selected from the group consisting of a metal, a metal oxide and a silicon dielectric material.

3. The method of claim 1, wherein the metal is copper (Cu),
wherein the nitride is titanium nitride (TiN), and
wherein the thin film is a hafnium oxide (HfO₂) thin film.

4. The method of claim 1, wherein Condition (1) below is satisfied:
A<B<C (1)
wherein in Condition (1) above, A represents the thickness of a thin film formed on a surface of the first substrate, B represents the thickness of a thin film formed on a surface of the second substrate, and C represents the thickness of a thin film formed on a surface of the third substrate.

5. The method of claim 1, wherein the organothiol small-molecule inhibitor comprises a compound represented by Chemical Formula 1 below:
R¹—S—R² [Chemical Formula 1]
wherein in Chemical Formula 1 above, R¹ and R² are each independently a C1 to C12 linear alkyl group, a C3 to C12 branched alkyl group or a C6 to C12 aryl group.

6. The method of claim 1, wherein step 2 comprises:
step 2-1 of drying the substrate, introducing the substrate into a chamber having an internal temperature of 300 to 500° C. and a vacuum base pressure condition, and maintaining for 1 to 20 minutes;
step 2-2 of purging the chamber, introducing an organothiol small-molecule inhibitor into the chamber while maintaining an internal temperature of the chamber at 200 to 500° C., and exposing the substrate to the organothiol small-molecule inhibitor for 1 to 100 seconds; and
step 2-3 of cooling the substrate exposed to the organothiol small-molecule inhibitor to a temperature of 15 to 35° C.

7. The method of claim 1, wherein in step 2, the surface of the first substrate exposed to the organothiol small-molecule inhibitor has a water contact angle of 90° to 100°, and
wherein the surface of the second substrate exposed to the organothiol small-molecule inhibitor has a water contact angle of 70° to 80°.

8. The method of claim 6, wherein the organothiol small-molecule inhibitor introduced into the chamber undergoes thermal dissociation, and is separated into alkylsulfanyl and alkyl, respectively, and
wherein the alkylsulfanyl is adsorbed on a surface of the first substrate, and the alkyl is adsorbed on a surface of the second substrate.

9. The method of claim 8, wherein the alkylsulfanyl is ethylsulfanyl, and
wherein the alkyl is ethyl.

10. The method of claim 1, wherein step 3 comprises:
step 3-1 of introducing a substrate exposed to the organothiol small-molecule inhibitor into a chamber, and heating to 200 to 350° C.; and
step 3-2 of performing area-selective atomic layer deposition as a cycle of introducing a precursor for thin-film deposition into the chamber, exposing for 1 to 10 seconds, purging for 50 to 70 seconds, introducing a counter reactant into the chamber, exposing for 1 to 5 seconds, and purging for 50 to 70 seconds.

11. The method of claim 10, wherein the precursor for thin-film deposition comprises at least one selected from a compound represented by Chemical Formula 2 below, a compound represented by Chemical Formula 3 below, a compound represented by Chemical Formula 4 below and a compound represented by Chemical Formula 5 below:
(L₁)ₙM(NR³R⁴)₄₋ₙ [Chemical Formula 2]
wherein in Chemical Formula 2 above, L₁ is a ligand selected from the group consisting of cyclopentadienyl and C1 to C12 alkyl-substituted cyclopentadienyl, M is a metal selected from the group consisting of titanium, hafnium and zirconium, R³ and R⁴ are each independently a C1 to C12 linear alkyl group or a C3 to C12 branched alkyl group, and n is 0, 1 or 2,
R⁵ₘM(OR⁶)₃₋ₘ [Chemical Formula 3]
wherein in Chemical Formula 3 above, M is a metal selected from the group consisting of aluminum, hafnium and zirconium, R⁵ and R⁶ are each independently a C1 to C12 linear alkyl group or a C3 to C12 branched alkyl group, and m is 1 to 3,
(L₂)ₚMR⁷(OR⁸)₃₋ₚ [Chemical Formula 4]
wherein in Chemical Formula 4 above, L₂ is a ligand selected from the group consisting of cyclopentadienyl and C1 to C12 alkyl-substituted cyclopentadienyl, M is a metal selected from the group consisting of titanium, hafnium and zirconium, R⁷ and R⁸ are each independently a C1 to C12 linear alkyl group or a C3 to C12 branched alkyl group, and p is 1 or 2, and
(R⁹N)_{q}M(NR¹⁰R¹¹)_{4-q} [Chemical Formula 5]
wherein in Chemical Formula 5 above, M is a metal selected from the group consisting of vanadium, niobium, tantalum, molybdenum and tungsten, R⁹, R¹⁰ and R¹¹ are each independently a C1 to C12 linear alkyl group or a C3 to C12 branched alkyl group, and q is 1 or 2.

12. The method of claim 11, wherein the compound represented by Chemical Formula 2 is tetrakis(dimethylamino)hafnium (TDMAH), tetrakis(diethylamino)hafnium (TDEAH), tetrakis(ethylmethylamino)hafnium (TEMAH), cyclopentadienyltris(dimethylamino)hafnium (CpHf(NMe₂)₃), methylcyclopentadienyltris(dimethylamino)hafnium ((MeCp)Hf(NMe₂)₃), ethylcyclopentadienyltris(dimethylamino)hafnium ((EtCp)Hf(NMe₂)₃), (n-propylcyclopentadienyl)tris(dimethylamino)hafnium ((n-PrCp)Hf(NMe₂)₃), cyclopentadienyltris(methylethylamino)hafnium (CpHf(NMeEt)₃), methylcyclopentadienyltris(methylethylamino)hafnium ((MeCp)Hf(NMeEt)₃), ethylcyclopentadienyltris(methylethylamino)hafnium ((EtCp)Hf(NMeEt)₃), cyclopentadienyltris(diethylamino)hafnium (CpHf(NEt₂)₃), methylcyclopentadienyltris(diethylamino)hafnium ((MeCp)Hf(NEt₂)₃), ethylcyclopentadienyltris(diethylamino)hafnium ((EtCp)Hf(NEt₂)₃), bis(cyclopentadienyl)bis(dimethylamino)hafnium (Cp₂Hf(NMe₂)₂), bis(methylcyclopentadienyl)bis(dimethylamino)hafnium ((MeCp)₂Hf(NMe₂)₂), bis(ethylcyclopentadienyl)bis(dimethylamino)hafnium ((EtCp)₂Hf(NMe₂)₂), bis(cyclopentadienyl)bis(methylethylamino)hafnium (Cp₂Hf(NMeEt)₂), bis(methylcyclopentadienyl)bis(methylethylamino)hafnium ((MeCp)₂Hf(NMeEt)₂), bis(ethylcyclopentadienyl)bis(methylethylamino)hafnium ((EtCp)₂Hf(NMeEt)₂), bis(cyclopentadienyl)bis(diethylamino)hafnium (Cp₂Hf(NEt₂)₂), bis(methylcyclopentadienyl)bis(diethylamino)hafnium ((MeCp)₂Hf(NEt₂)₃), bis(ethylcyclopentadienyl)bis(diethylamino)hafnium ((EtCp)₂Hf(NEt₂)₂) or (n-propylcyclopentadienyl)tris(dimethylamino)zirconium ((n-PrCp)Zr(NMe₂)₃),
wherein the compound represented by Chemical Formula 3 is trimethylaluminum, triethylaluminum, dimethylaluminum isopropoxide or diethylaluminum isopropoxide,
wherein the compound represented by Chemical Formula 4 is CpHfMe(OMe)₂, CpZrMe(OMe)₂, (MeCp)HfMe(OMe)₂, (MeCp)ZrMe(OMe)₂, (EtCp)HfMe(OMe)₂ or (EtCp)ZrMe(OMe), and
wherein the compound represented by Chemical Formula 5 is tert-butyliminotri(diethylamino)tantalum (TBTDET), tert-butyliminotri(dimethylamino)tantalum (TBTDMT), tert-butyliminotri(ethylmethylamino)tantalum (TBTEMT), ethyliminotri(diethylamino)tantalum (EITDET), ethyliminotri(dimethylamino)tantalum (EITDMT), ethyliminotri(ethylmethylamino)tantalum (EITEMT), tert-amyliminotri(dimethylamino)tantalum (TAIMAT), tert-amyliminotri(diethylamino)tantalum, pentakis(dimethylamino)tantalum, tert-amyliminotri(ethylmethylamino)tantalum, bis(tert-butylimino)bis(dimethylamino)tungsten (BTBMW), bis(tert-butylimino)bis(diethylamino)tungsten or bis(tert-butylimino)bis(ethylmethylamino)tungsten.

13. The method of claim 11, wherein the precursor for thin-film deposition comprises a compound represented by Chemical Formula 2-1 below: 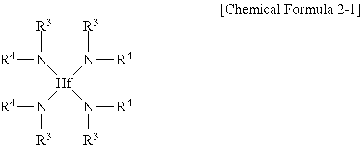
wherein in Chemical Formula 2-1 above, R₃ and R₄ are each independently a C1 to C12 linear alkyl group or a C3 to C12 branched alkyl group.

14. The method of claim 10, wherein the counter reactant comprises at least one selected from deionized water and hydrogen peroxide (H₂O₂).

15. The method of claim 10, wherein the area-selective atomic layer deposition is performed for 2 to 100 cycles.

16. The method of claim 10, wherein in the area-selective atomic layer deposition, a thin film with a thickness of 0.3 to 0.8 Å is formed on the surface of the first substrate per cycle,
wherein a thin film with a thickness of 0.8 to 1.5 Å is formed on the surface of the second substrate per cycle, and
wherein a thin film with a thickness of 1.5 to 2.5 Å is formed on the surface of the third substrate per cycle.

17. A substrate having thin films selectively formed thereon, comprising:
a substrate on which a first substrate comprising a metal, a second substrate comprising silicon dioxide (SiO₂) and a third substrate comprising a nitride are arranged in parallel and integrated; and
a thin film formed on a surface of the substrate,
wherein alkylsulfanyl is adsorbed on a surface of the first substrate, and alkyl is adsorbed on a surface of the second substrate, and
wherein the thickness of a thin film formed on a surface of the first substrate, the thickness of a thin film formed on a surface of the second substrate, and the thickness of a thin film formed on a surface of the third substrate are different.

18. The substrate of claim 17, wherein Condition (1) below is satisfied:
A<B<C (1)
wherein in Condition (1) above, A represents the thickness of a thin film formed on a surface of the first substrate, B represents the thickness of a thin film formed on a surface of the second substrate, and C represents the thickness of a thin film formed on a surface of the third substrate.

19. The substrate of claim 17, wherein the alkylsulfanyl is ethylsulfanyl, and
wherein the alkyl is ethyl.

20. The substrate of claim 17, wherein the metal of the first substrate is copper (Cu),
wherein the nitride of the third substrate is titanium nitride (TiN), and
wherein the thin film is a hafnium oxide (HfO₂) thin film.
